(19) United States
(12) Patent Application Publication
(10) Pub. No.: US 2026/0245840 A1
(43) Pub. Date: Aug. 20, 2026

(54) SUBSTRATE PROCESSING APPARATUS, TEMPERATURE CONTROL DEVICE, AND TEMPERATURE CONTROL METHOD

(71) Applicant: Tokyo Electron Limited, Tokyo (JP)

(72) Inventor: Takuya HARASHIMA, Miyagi (JP)

(73) Assignee: Tokyo Electron Limited, Tokyo (JP)

(21) Appl. No.: 19/646,727

(22) Filed: Apr. 14, 2026

Related U.S. Application Data
(63) Continuation of application No. PCT/JP2024/036382, filed on Oct. 11, 2024.

(30) Foreign Application Priority Data
Oct. 25, 2023 (JP) 2023-183353

(51) Int. Cl. H01J 37/32

(52) U.S. Cl. CPC H01J 37/32724

(57) ABSTRACT

A plasma processing system has a supply, a main body section, and controller circuitry. The supply supplying each of a plurality of heat media, the plurality of heat media having a different temperature. The main body section has, formed therein, a plurality of flow paths that respectively allow the plurality of heat media to separately flow therethrough, and is included in the plasma processing system. The controller circuitry performs control, when a first heat medium of the plurality of heat media is caused to flow through the plurality of flow paths from the supply, to cause a second heat medium of the plurality of heat media and other than the first heat medium to be discharged from the plurality of flow paths.

### CROSS-REFERENCE TO RELATED APPLICATIONS

This application is a continuation application of International Application PCT/JP2024/036382, filed on Oct. 11, 2024, and designating the U.S., and claims priority to Japanese Application No. 2023-183353, filed on Oct. 25, 2023, the entire contents of each of which are incorporated herein by reference.

### FIELD

The present disclosure relates to a substrate processing apparatus, a temperature control device, and a temperature control method.

### BACKGROUND

Japanese Laid-open Patent Publication No. 2013-105359 discloses “A temperature control system for controlling a temperature of a member used in a semiconductor manufacturing device, the temperature control system including: a low temperature adjusting unit that stores liquid adjusted to a first temperature; a high temperature adjusting unit that stores liquid adjusted to a second temperature higher than the first temperature; a low temperature flow path for passing the fluid supplied from the low temperature adjusting unit; a high temperature flow path for passing the fluid supplied from the high temperature adjusting unit; a bypass flow path for circulating fluid; a combination flow path that merges with the low temperature flow path, the high temperature flow path, and the bypass flow path at a merging portion, the combination flow path being for passing the fluid merged from each flow path; a temperature adjusting unit that is arranged at or near the member, is for passing the fluid from the combination flow path, and cools or heats the member; variable valves installed in the low temperature flow path, the high temperature flow path, and the bypass flow path and upstream of the merging portion; and a control device that controls degrees of opening of the variable valves and adjusts a flow rate distribution ratio among the low temperature flow path, the high temperature flow path, and the bypass flow path.”.

### SUMMARY

A substrate processing apparatus according to one aspect of the present disclosure includes a heat medium supply, a component and a controller. The heat medium supply supplies each of a plurality of heat media, the plurality of heat media having different temperatures from one another. The component is included in the substrate processing apparatus and having a plurality of flow paths formed in the component, the plurality of flow paths respectively allowing the plurality of heat media to separately flow through the plurality of flow paths. The controller circuitry is configured to perform control, when a first heat medium of the plurality of heat media is caused to flow to the plurality of flow paths from the heat medium supply, to cause a second heat medium of the plurality of heat media and other than the first heat medium to be discharged from the plurality of flow paths.

### BRIEF DESCRIPTION OF DRAWINGS

FIG. 1 is a diagram illustrating an example of a configuration of a capacitively coupled plasma processing apparatus.

FIG. 2 is a diagram illustrating an example of a schematic configuration of a temperature control device according to an embodiment.

FIG. 3A is a diagram illustrating control of a heat medium by the temperature control device according to the embodiment.

FIG. 3B is a diagram illustrating control of the heat medium by the temperature control device according to the embodiment.

FIG. 3C is a diagram illustrating control of the heat medium by the temperature control device according to the embodiment.

FIG. 3D is a diagram illustrating control of the heat medium by the temperature control device according to the embodiment.

FIG. 3E is a diagram illustrating control of the heat medium by the temperature control device according to the embodiment.

FIG. 4A is a diagram illustrating flows of heat in a main body section during plasma processing.

FIG. 4B is a diagram illustrating flows of heat in the main body section during the plasma processing.

FIG. 5 is a diagram illustrating an example of another configuration of the temperature control device according to the embodiment.

FIG. 6A is a diagram illustrating an example of another configuration of the temperature control device according to the embodiment.

FIG. 6B is a diagram illustrating an example of another configuration of the temperature control device according to the embodiment.

FIG. 7A is a diagram illustrating an example of another configuration of the temperature control device according to the embodiment.

FIG. 7B is a diagram illustrating the example of another configuration of the temperature control device according to the embodiment.

FIG. 8 is a diagram schematically illustrating another example of a configuration of a substrate support unit.

FIG. 9 is a diagram illustrating an example of a configuration of a main body section 111 according to the embodiment.

FIG. 10 is a flowchart illustrating an example of a processing flow of a temperature control method according to the embodiment.

### DESCRIPTION OF EMBODIMENTS

Embodiments of a substrate processing apparatus, a temperature control device, and a temperature control method will hereinafter be described in detail on the basis of the drawings. The substrate processing apparatus, the temperature control device, and the temperature control method disclosed herein are not to be limited by the following embodiments.

The present disclosure provides a technique for shortening time for temperature of a component to stabilize.

In a known substrate processing apparatus, a flow path is formed in a component included in the substrate processing apparatus, the component being, for example, a stage where a substrate is placed, and temperature of a heat medium circulated to the flow path is changed to thereby control temperature of the component.

However, in a case where the temperature of the component is to be raised or lowered by changing the temperature of the heat medium circulated to the flow path, time is taken for the temperature of the component to stabilize. Therefore, a technique for shortening the time for the temperature of the component to stabilize is hoped for.

### Embodiments

### Configuration of Substrate Processing Apparatus

The following description is on an example of a substrate processing apparatus of the present disclosure. With respect to embodiments described hereinafter, a case where the substrate processing apparatus of the present disclosure is implemented as a plasma processing system having a system configuration will be described as an example.

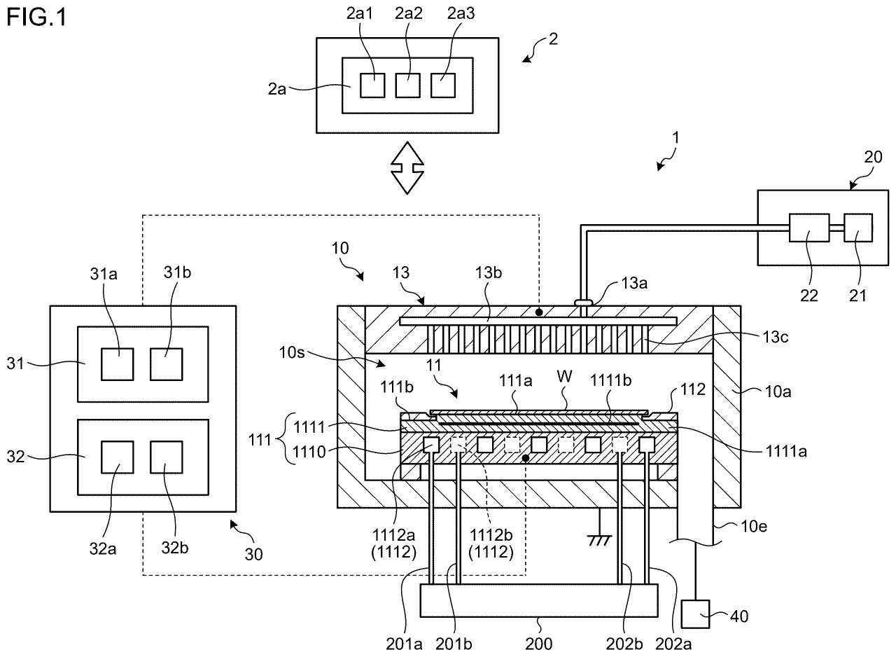

An example of a configuration of the plasma processing system will be described hereinafter. FIG. 1 is a diagram illustrating an example of a configuration of a capacitively coupled plasma processing apparatus.

This plasma processing system includes a capacitively coupled plasma processing apparatus 1 and a controller 2. The capacitively coupled plasma processing apparatus 1 includes a plasma processing chamber 10, a gas supply unit 20, a power source 30, and an exhaust system 40. Furthermore, the plasma processing apparatus 1 includes a substrate support unit 11 and a gas introduction unit. The gas introduction unit is configured to introduce at least one processing gas into the plasma processing chamber 10. The gas introduction unit includes a shower head 13. The substrate support unit 11 is arranged in the plasma processing chamber 10. The shower head 13 is arranged above the substrate support unit 11. In one embodiment, the shower head 13 is at least part of a ceiling of the plasma processing chamber 10. The plasma processing chamber 10 has a plasma processing space 10s defined by the shower head 13, a side wall 10a of the plasma processing chamber 10, and the substrate support unit 11. The plasma processing chamber 10 has at least one gas supply port for supplying at least one processing gas to the plasma processing space 10s and at least one gas discharge port for discharging gas from the plasma processing space. The plasma processing chamber 10 is grounded. The shower head 13 and the substrate support unit 11 are electrically insulated from a housing of the plasma processing chamber 10. The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium, such as a CD-ROM or DVD, and/or the memory of a FPGA or ASIC.

The substrate support unit 11 includes a main body section 111 and a ring assembly 112. In this embodiment, the main body section 111 corresponds to a component, a stage, and a target member, of the present disclosure. The main body section 111 has a central area 111a for supporting a substrate W and an annular area 111b for supporting the ring assembly 112. A wafer is an example of the substrate W. The annular area 111b of the main body section 111 surrounds the central area 111a of the main body section 111 in a plan view. The substrate W is arranged on the central area 111a of the main body section 111, and the ring assembly 112 is arranged on the annular area 111b of the main body section 111 so that the ring assembly 112 surrounds the substrate W on the central area 111a of the main body section 111. Therefore, the central area 111a is also called a substrate support surface for supporting the substrate W and the annular area 111b is also called a ring support surface for supporting the ring assembly 112. In the embodiment, the central area 111a corresponds to a placing surface of the present disclosure.

In one embodiment, the main body section 111 includes a base 1110 and an electrostatic chuck 1111. The base 1110 includes an electrically conductive member. The electrically conductive member of the base 1110 may function as a lower electrode. The electrostatic chuck 1111 is arranged on the base 1110. The electrostatic chuck 1111 includes a ceramic member 1111a and an electrostatic electrode 1111b arranged in the ceramic member 1111a. The ceramic member 1111a has the central area 111a. In one embodiment, the ceramic member 1111a also has the annular area 111b. Another member surrounding the electrostatic chuck 1111 may have the annular area 111b, that member being, for example, an annular electrostatic chuck or an annular insulating member. In this case, the ring assembly 112 may be arranged on the annular electrostatic chuck or annular insulating member, or may be arranged on both the electrostatic chuck 1111 and the annular insulating member. Furthermore, at least one RF/DC electrode coupled to a later described radio frequency (RF) power source 31 and/or a later described direct current (DC) power source 32 may be arranged in the ceramic member 1111a. In this case, that at least one RF/DC electrode functions as a lower electrode. In a case where a later described bias RF signal and or a later described DC signal is supplied to that at least one RF/DC electrode, the RF/DC electrode is also called a bias electrode. The electrically conductive member of the base 1110 and that at least one RF/DC electrode may function as a plurality of lower electrodes. Furthermore, the electrostatic electrode 1111b may function as a lower electrode. Therefore, the substrate support unit 11 includes at least one lower electrode.

The ring assembly 112 includes one or more annular members. In one embodiment, these one or more annular members include one or more edge rings and at least one cover ring. The edge ring or rings are formed of an electrically conductive material or an insulating material, and the cover ring or rings are formed of an insulating material.

Furthermore, the substrate support unit 11 may include a temperature adjusting module configured to adjust at least one of the electrostatic chuck 1111, the ring assembly 112, and the substrate to a target temperature. The temperature adjusting module may include a heater, a heat transfer medium, a flow path, or a combination thereof.

In one embodiment, the substrate support unit 11 has, formed therein, a plurality of flow paths 1112 that each allow liquid, such as brine, or a heat medium, such as gas, to flow therethrough, and one or more heaters are arranged in the ceramic member 1111a of the electrostatic chuck 1111. Furthermore, the substrate support unit 11 may include a heat transfer gas supply unit configured to supply heat transfer gas to a gap between a reverse face of the substrate W and the central area 111a. The plurality of flow paths 1112 do not intersect with one another and allow the heat medium in each of the flow paths 1112 to flow separately therethrough without being mixed. The main body section 111 of the substrate support unit 11 according to the embodiment has two flow paths 1112a and 1112b formed therein. The flow paths 1112a and 1112b are formed below the central area 111a, to not intersect with each other. The flow paths 1112a and 1112b are formed in parallel and has a partition wall provided therebetween. The flow path 1112a has a pipe 201a connected to one end of the flow path 1112a, and a pipe 202a connected to the other end of the flow path 1112a. The flow path 1112b has a pipe 201b connected to one end of the flow path 1112b, and a pipe 202b connected to the other end of the flow path 1112b. The pipes 201a and 201b and the pipes 202a and 202b are connected to a temperature control device 200. The temperature control device 200 controls temperature of the main body section 111 by controlling the heat medium caused to flow to the flow paths 1112a and 1112b via the pipes 201a and 201b and the pipes 202a and 202b.

The shower head 13 is configured to introduce at least one processing gas from the gas supply unit 20 into the plasma processing space 10s. The shower head 13 has at least one gas supply port 13a, at least one gas diffusion chamber 13b, and a plurality of gas introduction ports 13c. Processing gas supplied to the gas supply port 13a passes through the gas diffusion chamber 13b and is introduced into the plasma processing space 10s from the plurality of gas introduction ports 13c. Furthermore, the shower head 13 includes at least one upper electrode. The gas introduction unit may include, in addition to the shower head 13, one or more side gas injectors (SGIs) attached to one or more openings formed in the side wall 10a.

The gas supply unit 20 may include at least one gas source 21 and at least one flow controller 22. In one embodiment, the gas supply unit 20 is configured to supply at least one processing gas to the shower head 13 via the flow controller or controllers 22 respectively corresponding to that at least one processing gas from the gas source or sources 21 respectively corresponding to that at least one processing gas. Each of the flow controllers 22 may include, for example, a mass flow controller or a pressure controlled flow controller. Furthermore, the gas supply unit 20 may include one or more flow modulation devices that modulate or pulse flow of at least one processing gas.

The power source 30 includes the RF power source 31 coupled to the plasma processing chamber 10 via at least one impedance matching circuit. The RF power source 31 is configured to supply at least one RF signal (RF power) to at least one lower electrode and/or at least one upper electrode. Plasma is thereby formed from at least one processing gas supplied to the plasma processing space 10s. Therefore, the RF power source 31 may function as at least part of a plasma generation unit configured to generate plasma from one or more processing gases in the plasma processing chamber 10. Furthermore, supplying a bias RF signal to at least one lower electrode generates a bias potential on the substrate W and enables ionic components in the formed plasma to be drawn to the substrate W.

In one embodiment, the RF power source 31 includes a first RF generation unit 31a and a second RF generation unit 31b. The first RF generation unit 31a is coupled to at least one lower electrode and/or at least one upper electrode via at least one impedance matching circuit and is configured to generate a source RF signal (source RF power) for plasma generation. In one embodiment, the source RF signal has a frequency in a range of 10 MHz to 150 MHz. In one embodiment, the first RF generation unit 31a may be configured to generate a plurality of source RF signals having different frequencies. The one or more source RF signals generated are supplied to at least one lower electrode and/or at least one upper electrode.

The second RF generation unit 31b is coupled to at least one lower electrode via at least one impedance matching circuit and is configured to generate a bias RF signal (bias RF power). The bias RF signal may have a frequency that is the same as or different from the frequency of the source RF signal. In one embodiment, the bias RF signal has a frequency lower than the frequency of the source RF signal. In one embodiment, the bias RF signal has a frequency in a range of 100 kHz to 60 MHz. In one embodiment, the second RF generation unit 31b may be configured to generate a plurality of bias RF signals having different frequencies. The generated one or more bias RF signals are supplied to at least one lower electrode. Furthermore, in various embodiments, at least one of: the source RF signal or signals; and the bias RF signal or signals may be pulsed.

Furthermore, the power source 30 may include the DC power source 32 coupled to the plasma processing chamber 10. The DC power source 32 includes a first DC generation unit 32a and a second DC generation unit 32b. In one embodiment, the first DC generation unit 32a is connected to at least one lower electrode and is configured to generate a first DC signal. The generated first bias DC signal is supplied to at least one lower electrode. In one embodiment, the second DC generation unit 32b is connected to at least one upper electrode and is configured to generate a second DC signal. The generated second DC signal is supplied to at least one upper electrode.

In various embodiments, at least one of the first and second DC signals may be pulsed. In this case, a sequence of voltage pulses is applied to at least one lower electrode and/or at least one upper electrode. The voltage pulses may have a pulse waveform that is rectangular, trapezoidal, or triangular, or a combination thereof. In one embodiment, a waveform generation unit for generating a sequence of voltage pulses from a DC signal is connected between the first DC generation unit 32a and at least one lower electrode. Therefore, the first DC generation unit 32a and the waveform generation unit are included in a voltage pulse generation unit. In a case where the second DC generation unit 32b and the waveform generation unit are included in the voltage pulse generation unit, the voltage pulse generation unit is connected to at least one upper electrode. The voltage pulses may have a positive polarity or a negative polarity. Furthermore, the sequence of the voltage pulses may include one or more positive polarity voltage pulses and one or more negative polarity voltage pulses, in one cycle. The first and second DC generation units 32a and 32b may be provided in addition to the RF power source 31, or the first DC generation unit 32a may be provided instead of the second RF generation unit 31b.

The exhaust system 40 may be connected to, for example, a gas discharge port 10e provided in a bottom portion of the plasma processing chamber 10. The exhaust system 40 may include a pressure regulating valve and a vacuum pump. The pressure regulating valve regulates pressure in the plasma processing space 10s. The vacuum pump may include a turbomolecular pump, a dry pump, or a combination thereof.

The controller 2 processes computer-executable commands that cause the plasma processing apparatus 1 to execute various processes set forth in the present disclosure. The controller 2 may be configured to control each element of the plasma processing apparatus 1 to execute various processes set forth herein. In one embodiment, part or all of the controller 2 may be included in the plasma processing apparatus 1. The controller 2 may include a processing unit 2a1, a storage 2a2, and a communication interface 2a3. The controller 2 is implemented by, for example, a computer 2a. The processing unit 2a1 may be configured to perform various control operation by reading a program from the storage 2a2 and executing the read program. The program may be stored in the storage 2a2 beforehand or may be obtained via a medium when needed. The obtained program is stored in the storage 2a2, and read and executed by the processing unit 2a1 from the storage 2a2. The medium may be any of various storage media that are able to be read by the computer 2a and may be a communication line connected to the communication interface 2a3. The processing unit 2a1 may be a central processing unit (CPU). The storage 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line, such as a local area network (LAN).

### Configuration of Temperature Control Device 200

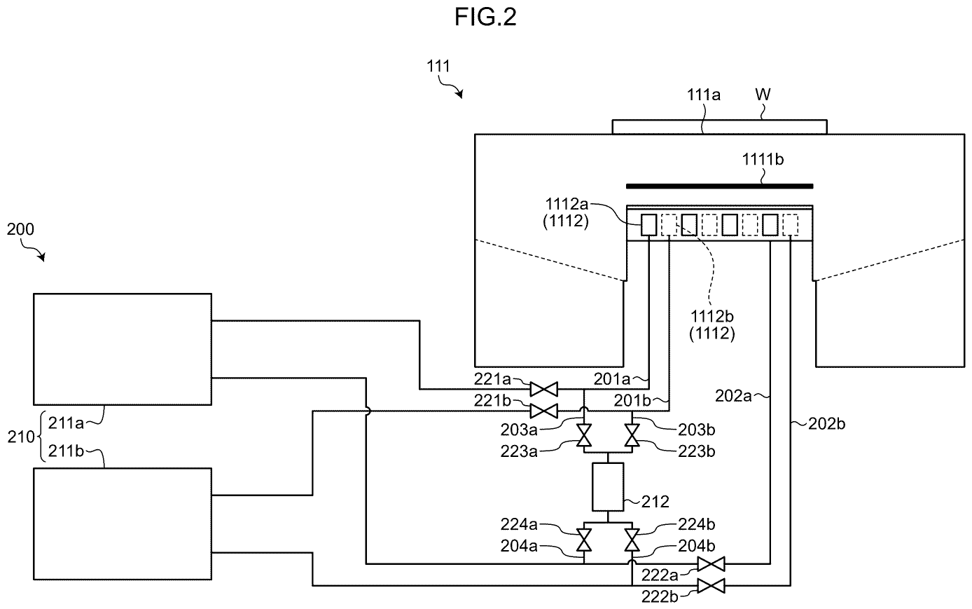

A schematic configuration of the temperature control device 200 that controls temperature of the main body section 111 of the substrate support unit 11 will be described next. FIG. 2 is a diagram illustrating an example of the schematic configuration of the temperature control device 200 according to the embodiment. FIG. 2 illustrates a configuration of the main body section 111 in a simplified manner.

The temperature control device 200 has a supply unit 210. In the embodiment, the supply unit 210 corresponds to a heat medium supply unit (i.e., heat medium supply) of the present disclosure. The supply unit 210 is configured to be capable of supplying each of a plurality of heat media each having a different temperature. The heat media may be liquid or gas, selected based on the temperatures to be controlled. A case where the heat media are liquid will be described with respect to the embodiment. A liquid material that has fluidity in a liquid state at the temperatures to be controlled and has high stability and high heat transfer performance is used as the heat media. Furthermore, in a case where a source RF signal or a bias RF signal is supplied to the plasma processing chamber 10, a liquid material that is highly insulating is used as the heat media. The plurality of heat media may be the same liquid material or different liquid materials. A liquid heat medium may be, for example, cooling water, antifreeze, or an organic solvent. Furthermore, the organic solvent may be a fluorinated fluid, for example, Galden (registered trademark), Novec 7200 (registered trademark), or Fluorinert (registered trademark). The heat media are not necessarily liquid and may be gas such as air, nitrogen (N2), or carbon dioxide (CO2) controlled to predetermined temperatures. Furthermore, a heat medium may be a gas-liquid two-phase fluid in which part of the liquid heat medium has been vaporized and mixed with the liquid. The supply unit 210 is configured to store each of the plurality of heat media each adjusted to a different temperature and to be capable of supplying each of the plurality of heat media. The supply unit 210 according to the embodiment has two retaining units 211a and 211b. The pipe 201a and the pipe 202a are connected to the retaining unit 211a. The pipe 201b and the pipe 202b are connected to the retaining unit 211b.

The retaining unit 211a is configured to be capable of supplying a heat medium at a first temperature. The retaining unit 211b is configured to be capable of supplying a heat medium at a second temperature higher than the first temperature. For example, the retaining unit 211a has a tank that stores the heat medium and controls temperature of the heat medium to the first temperature by controlling temperature of the tank. The retaining unit 211a supplies the heat medium at the first temperature to the pipe 201a from the tank. The retaining unit 211b has a tank that stores the heat medium and controls temperature of the heat medium to the second temperature higher than the first temperature by controlling temperature of the tank. The retaining unit 211b supplies the heat medium at the second temperature to the pipe 201b from the tank.

The pipe 201a transports the heat medium from the retaining unit 211a to the flow path 1112a. The pipe 201b transports the heat medium from the retaining unit 211b to the flow path 1112b. The pipe 202a transports the heat medium from the flow path 1112a to the retaining unit 211a. The pipe 202b transports the heat medium from the flow path 1112b to the retaining unit 211b. The pipe 201a is provided with a valve 221a capable of opening and closing the pipe 201a. The pipe 201b is provided with a valve 221b capable of opening and closing the pipe 201b. The pipe 202a is provided with a valve 222a capable of opening and closing the pipe 202a. The pipe 202b is provided with a valve 222b capable of opening and closing the pipe 202b. Hereinafter, the pipes 201a and 201b may be collectively referred to as pipes 201, and the pipes 202a and 202b may be collectively referred to as pipes 202. Furthermore, hereinafter, the valves 221a and 221b may be collectively referred to as valves 221 and the valves 222a and 222b may be collectively referred to as valves 222. In the embodiment, the pipes 201 correspond to first pipes of the present disclosure and the pipes 202 correspond to second pipes of the present disclosure. Furthermore, in the embodiment, the valves 221 correspond to first valves of the present disclosure and the valves 222 correspond to fourth valves of the present disclosure.

The pipes 201a and 201b are respectively provided with pipes 203a and 203b branching off therefrom. The pipe 203a branches off from the pipe 201a at a position on one side of the valve 221a, the one side being toward the flow path 1112a. The pipe 203b branches off from the pipe 201b at a position on one side of the valve 221b, the one side being toward the flow path 1112b. The pipe 203a is provided with a valve 223a capable of opening and closing the pipe 203a. The pipe 203b is provided with a valve 223b capable of opening and closing the pipe 203b. Hereinafter, the pipes 203a and 203b may be collectively referred to as pipes 203 and the valves 223a and 223b may be collectively referred to as valves 223. In the embodiment, the pipes 203 correspond to third pipes of the present disclosure and the valves 223 correspond to second valves of the present disclosure.

The pipes 203a and 203b are connected to a tank 212. The tank 212 is arranged at a position lower than that of the main body section 111 and is capable of storing a heat medium. In the embodiment, the tank 212 corresponds to a first tank of the present disclosure.

Pipes 204a and 204b are connected to the tank 212. The pipe 204a is provided with a valve 224a capable of opening and closing the pipe 204a. The pipe 204b is provided with a valve 224b capable of opening and closing the pipe 204b. The pipe 204a is connected to the pipe 202a on one side of the valve 222a, the one side being toward the retaining unit 211a. The pipe 204b is connected to the pipe 202b on one side of the valve 222b, the one side being toward the retaining unit 211b. Hereinafter, the pipes 204a and 204b may be collectively referred to as pipes 204 and the valves 224a and 224b may be collectively referred to as valves 224. In the embodiment, the pipes 204 correspond to fourth pipes of the present disclosure and the valves 224 correspond to third valves of the present disclosure.

The heat medium circulating from the retaining unit 211a and the heat medium circulating from the retaining unit 211b are retained in the tank 212 separately and a plurality of the tanks 212 may thus be provided. For example, two tanks 212 may be provided, the pipe 203a and the pipe 204a may be connected to one of these tanks 212, and the pipe 203b and the pipe 204b may be connected to the other one of the tanks 212.

The valves 221a and 221b, the valves 222a and 222b, the valves 223a and 223b, and the valves 224a and 224b are each able to be switched open or closed under control by the controller 2. The controller 2 controls opening and closing of the valves 221a and 221b, the valves 222a and 222b, the valves 223a and 223b, and the valves 224a and 224b to thereby control the heat media caused to flow to the flow paths 1112a and 1112b.

### Control of Heat Media

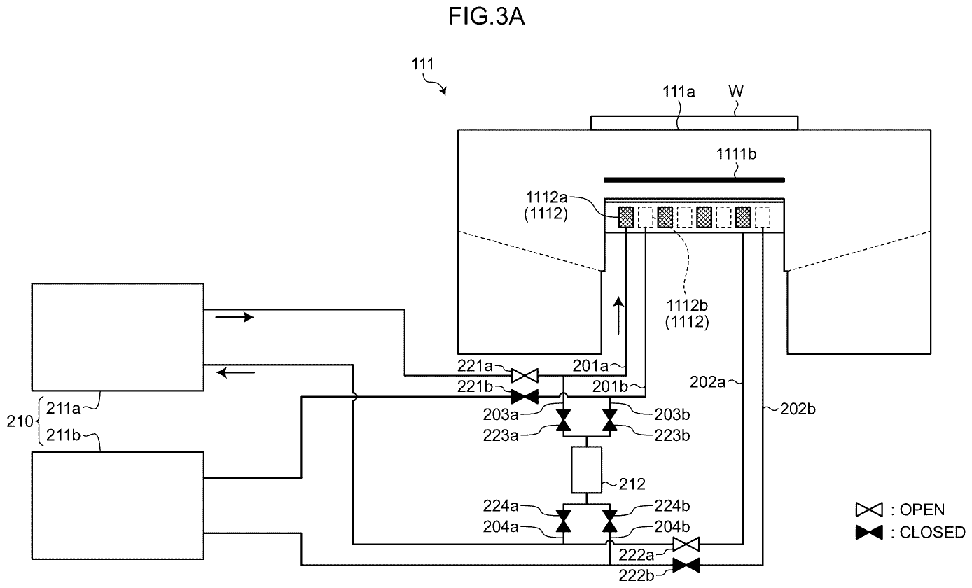

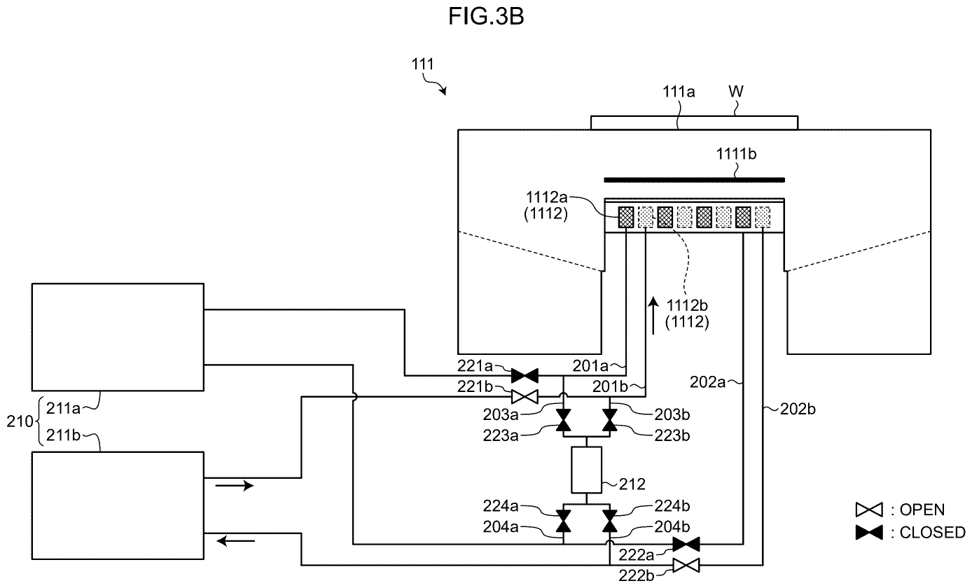

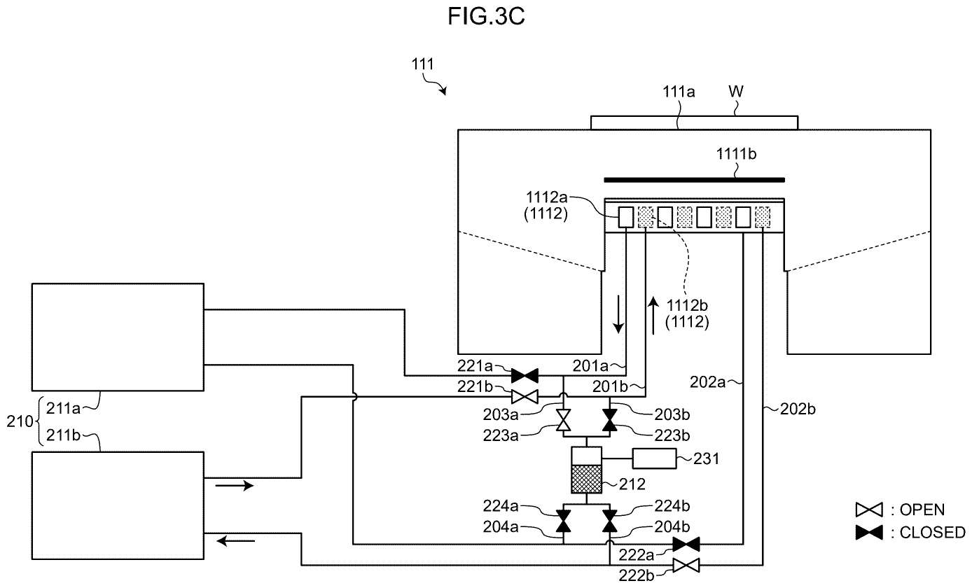

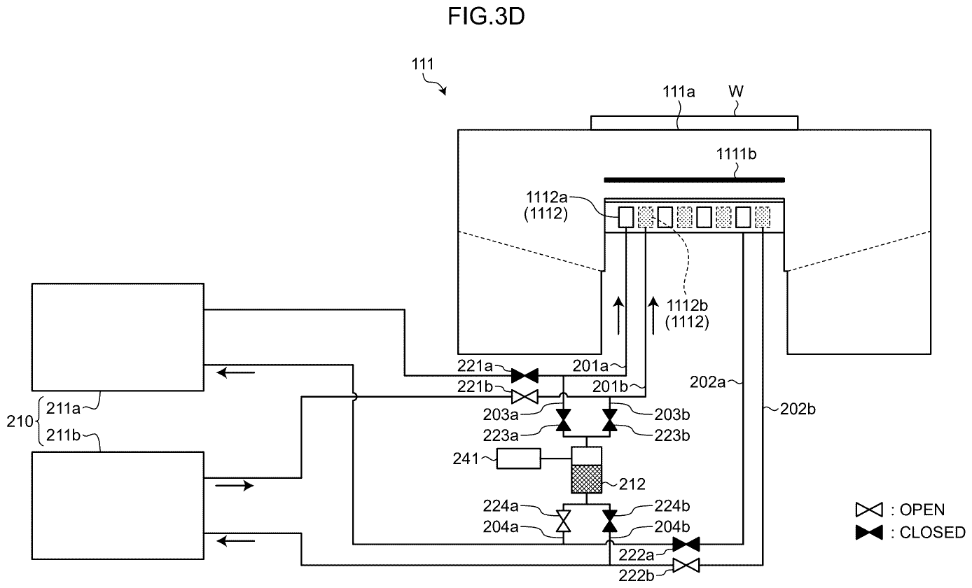

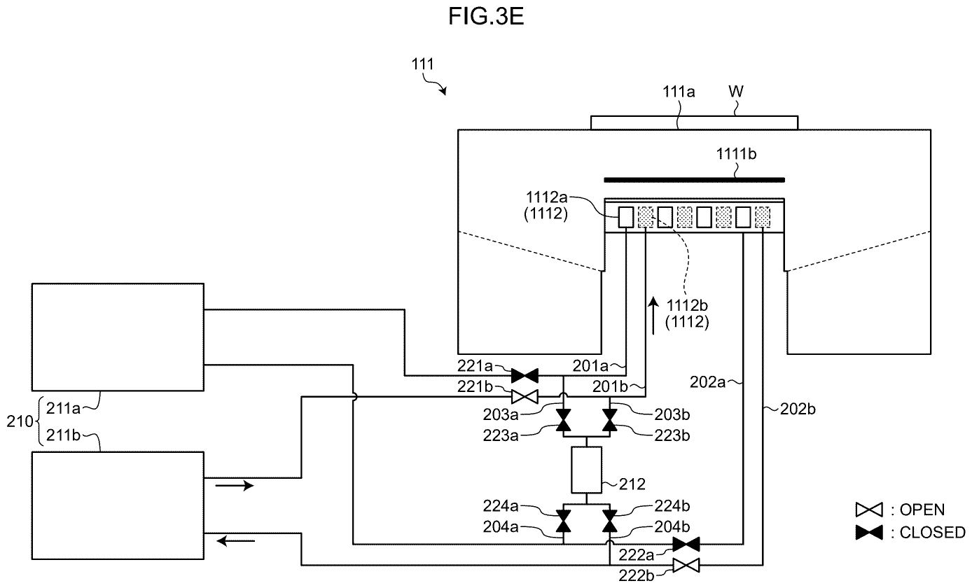

Control of the heat media by the temperature control device 200 will be described next. FIG. 3A to FIG. 3E are diagrams illustrating control of the heat media by the temperature control device 200 according to the embodiment. In FIG. 3A to FIG. 3E, valves in an open state are drawn unfilled and valves in a closed state are drawn filled.

The supply unit 210 supplies each of the plurality of heat media each having a different temperature. For example, the supply unit 210 supplies the heat medium at the first temperature from the retaining unit 211a to the pipe 201a and supplies the heat medium at the second temperature from the retaining unit 211b to the pipe 201b.

In a case where the heat medium at the first temperature is to be circulated to the main body section 111, the controller 2 controls the valve 221a and the valve 222a to be in the open state and controls the valve 223a and the valve 224a to be in the closed state. As illustrated in FIG. 3A, the heat medium at the first temperature supplied from the retaining unit 211a thereby flows through the flow path 1112a via the pipe 201a. The heat medium that has passed through the flow path 1112a and has been discharged from the flow path 1112a returns to the retaining unit 211a via the pipe 202a. The heat medium at the first temperature is circulated to the main body section 111 and temperature of the main body section 111 is thereby controlled by the heat medium flowing through the flow path 1112a.

Control for switching the heat medium to be circulated to the main body section 111 will be described next. In a case where the heat medium to be circulated to the main body section 111 is to be switched from the heat medium at the first temperature to the heat medium at the second temperature, the controller 2 controls the valve 221a and the valve 222a to be in the closed state and controls the valve 221b and the valve 222b to be in the open state. As illustrated in FIG. 3B, the heat medium at the second temperature supplied from the retaining unit 211b thereby flows through the flow path 1112b via the pipe 201b. The heat medium that has passed through the flow path 1112b and has been discharged from the flow path 1112b returns to the retaining unit 211b via the pipe 202b. The heat medium at the first temperature on the other hand stops flowing to the flow path 1112a because the valve 221a has been closed. The heat medium at the second temperature is circulated to the main body section 111 and the temperature of the main body section 111 is thereby controlled by the heat medium flowing through the flow path 1112b.

By the valve 221b and the valve 222b being brought into the open state, the heat medium is retained in the flow path 1112a. In the main body section 111, heat from the heat medium at the second temperature flowing through the flow path 1112b is absorbed by the heat medium retained in the flow path 1112a, via the main body section 111. Furthermore, heat capacity of the main body section 111 increases by an amount corresponding to the heat medium retained in the flow path 1112a. As a result, temperature change in the main body section 111 is moderated and a longer time is taken for the temperature to stabilize.

The controller 2 is thus configured to perform control so that in a case where a first heat medium of the plurality of heat media is caused to flow to a flow path 1112, a heat medium of the plurality of heat media and other than the first heat medium is discharged from a flow path 1112. For example, in a case where the heat medium at the second temperature is caused to flow to the flow path 1112b, the controller 2 performs control so that a heat medium is discharged from the flow path 1112a. Furthermore, in a case where the heat medium at the first temperature is caused to flow to the flow path 1112a, the controller 2 performs control so that a heat medium is discharged from the flow path 1112b. For example, as illustrated in FIG. 3B, in a case where the heat medium caused to flow is switched to cause the heat medium at the second temperature to flow through the flow path 1112b, the controller 2 controls the valve 223a to be in the open state. As illustrated in FIG. 3C, the heat medium that has been retained in the flow path 1112a flows into the tank 212 via the pipe 201a and the pipe 203a and the heat medium is thus discharged from the flow path 1112a. The heat medium that has flowed into the tank 212 is retained in the tank 212. Absorption of the heat, via the main body section 111, from the heat medium at the second temperature flowing through the flow path 1112b by the heat medium retained in the flow path 1112a is thereby able to be reduced. Furthermore, the increase in the heat capacity of the main body section 111 due to the retainment of the heat medium in the flow path 1112a is able to be reduced. As a result, the time taken for the temperature of the main body section 111 to stabilize is able to be shortened.

In a case where a heat medium is to be discharged from a flow path 1112, the interior of the tank 212 may be depressurized. For example, as illustrated in FIG. 3C, an exhaust unit 231 to exhaust the interior of the tank 212 is connected to the tank 212. In the embodiment, the exhaust unit 231 corresponds to a first depressurizing unit of the present disclosure. In a case where a heat medium is to be discharged from the flow path 1112a or 1112b, the controller 2 controls the exhaust unit 231 to depressurize the interior of the tank 212 by exhausting the interior of the tank 212 by means of the exhaust unit 231. The exhaust unit 231 may be the exhaust system 40, or an exhaust device provided separately from the exhaust system 40. In the case where the heat medium is to be discharged from the flow path 1112a or 1112b, depressurizing the interior of the tank 212 causes the heat medium in the flow path 1112a or 1112b to be sucked into the tank 212 and discharged quickly from the flow path 1112.

The heat medium retained in the tank 212 is able to be returned by controlling as follows. For example, in a case where the heat medium retained in the tank 212 is to be returned to the retaining unit 211a, the controller 2 controls the valve 224a to be in the open state as illustrated in FIG. 3D. In the case where the heat medium retained in the tank 212 is to be returned to the retaining unit 211a, the controller 2 preferably controls the valve 223a to be in the closed state. In FIG. 3D, the controller 2 controls the valve 224a to be in the open state and also controls the valve 223a to be in the closed state, when the heat medium at the second temperature is being circulated to the main body section 111. The heat medium retained in the tank 212 thereby flows into the retaining unit 211a via the pipe 204a and the pipe 202a.

In a case where the heat medium retained in the tank 212 is caused to flow to the retaining unit 211a or 211b, the interior of the tank 212 may be pressurized. For example, as illustrated in FIG. 3D, a gas supply unit 241 to supply a purge gas is connected to the tank 212. In the embodiment, the gas supply unit 241 corresponds to a first pressurizing unit of the present disclosure. In a case where the heat medium retained in the tank 212 is caused to flow to the retaining unit 211a or 211b, the controller 2 controls the gas supply unit 241 to supply the purge gas to the tank 212 from the gas supply unit 241 to pressurize the interior of the tank 212. The purge gas may be, for example, dry air. The gas supply unit 241 may be the gas supply unit 20 or a gas supply unit provided separately from the gas supply unit 20. Pressurizing the interior of the tank 212 causes the heat medium retained in the tank 212 to be pushed by pressure in the tank 212 and flow quickly into the retaining unit 211a or 211b. In a case where the controller 2 has finished returning the heat medium retained in the tank 212 to the retaining unit 211a, the controller 2 controls the valve 224a to be in the closed state, as illustrated in FIG. 3E.

By using a control method similar to that described above, the controller 2 is able to switch the heat medium to be circulated to the main body section 111 from the heat medium at the second temperature to the heat medium at the first temperature. For example, the controller 2 controls the valve 221a and the valve 222a to be in the open state and the valve 221b and the valve 222b to be in the closed state. Furthermore, in a case where the heat medium at the first temperature is caused to flow through the flow path 1112a, the controller 2 performs control so that a heat medium is discharged from the flow path 1112b. For example, the controller 2 controls the valve 223b to be in the open state. Furthermore, in a case where the heat medium retained in the tank 212 is to be returned to the retaining unit 211b, the controller 2 controls the valve 224b to be in the open state.

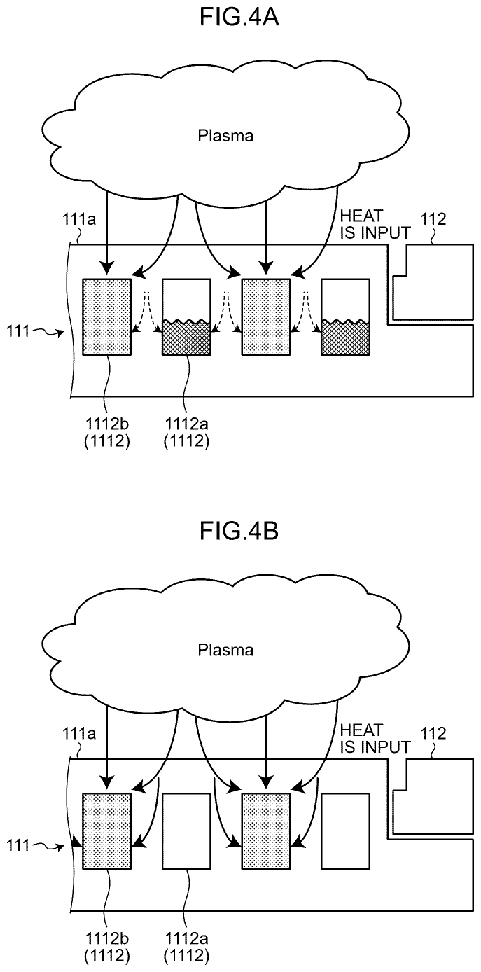

Flows of heat in the main body section 111 during plasma processing will be described next. FIG. 4A and FIG. 4B are diagrams illustrating the flows of heat in the main body section 111 during the plasma processing. In the plasma processing apparatus 1, during the plasma processing, heat from plasma is input to the main body section 111 via the substrate W or directly. The temperatures of the plurality of heat media supplied by the supply unit 210 are set so that the substrate W reaches respective predetermined temperatures, in consideration of temperature rises caused by the heat input from the plasma and heating by a heater provided in the main body section 111. For example, in a case where the plasma processing apparatus 1 performs a process A and a process B through the plasma processing, the first temperature is set so that the substrate W reaches a temperature suitable for the process A. The second temperature is set so that the substrate W reaches a temperature suitable for the process B. FIG. 4A and FIG. 4B illustrate a case where a heat medium is circulated to the flow path 1112b and a heat medium is discharged from the flow path 1112a for the process B to be performed after the process A. FIG. 4A illustrates a case where part of the heat medium is remaining in the flow path 1112a even though the heat medium is discharged from the flow path 1112a. FIG. 4B illustrates a case where the heat medium has been discharged from the flow path 1112a and the heat medium has been removed completely from the flow path 1112a. In the process B, inputting the heat from the plasma and removing the heat by means of the heat medium circulated through the flow path 1112b cause the substrate W to reach the temperature suitable for the process B. As illustrated in FIG. 4B, in a case where the heat medium has been removed completely from the flow path 1112a, the heat from the plasma is input to the heat medium in the flow path 1112b. The time for the temperature of the substrate W to stabilize at the temperature suitable for the process B is thereby able to be shortened. Furthermore, even in the case where part of the heat medium is remaining in the flow path 1112a as illustrated in FIG. 4A, the liquid surface of the heat medium is separated from an upper surface of the flow path 1112a in the flow path 1112a, a space without the heat medium is thus formed near the central area 111a, and heat transfer is thereby hindered. The heat from the plasma is thereby input mainly to the heat medium in the flow path 1112b. Therefore, even in the case where part of the heat medium is remaining in the flow path 1112a as illustrated in FIG. 4A, the time for the temperature of the main body section 111 to stabilize is able to be shortened and the time for the substrate W to stabilize at the temperature suitable for the process B is thereby able to be shortened.

The above described configuration of the temperature control device 200 is an example, the configuration is not to be limited to this example, and an example of another configuration of the temperature control device 200 will be described next.

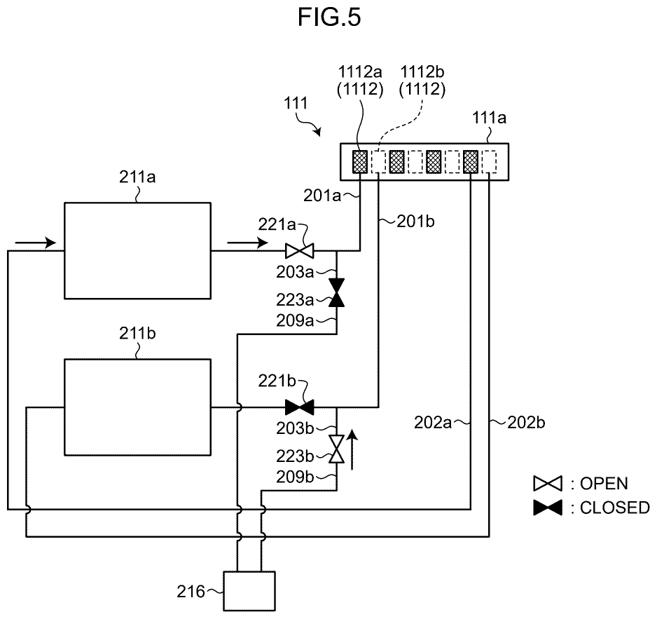

FIG. 5 is a diagram illustrating an example of another configuration of the temperature control device 200 according to the embodiment. The temperature control device 200 illustrated in FIG. 5 is partly the same as the temperature control device 200 illustrated in FIG. 2, and the same reference sign will thus be assigned to portions that are the same, description of the same portions will be omitted, and portions that are different will be described mainly.

In the temperature control device 200 illustrated in FIG. 5, a pipe 209a is connected to the pipe 203a and a pipe 209b is connected to the pipe 203b. The pipes 209a and 209b are connected to a gas supply unit 216. The gas supply unit 216 is capable of supplying a purge gas to each of the pipes 209a and 209b. The gas supply unit 216 may be the gas supply unit 20 or a gas supply unit provided separately from the gas supply unit 20.

In a case where the heat medium at the first temperature is to be circulated to the main body section 111, the controller 2 controls the valve 221a to be in the open state and controls the valve 221b and the valve 223a to be in the closed state. The heat medium at the first temperature thereby circulates through the retaining unit 211a and the flow path 1112a in the main body section 111 via the pipe 201a and the pipe 202a. Furthermore, in a case where the heat medium at the first temperature is caused to flow to the flow path 1112a, the controller 2 performs control so that a heat medium is discharged from the flow path 1112b. For example, as illustrated in FIG. 5, the controller 2 controls the valve 223b to be in the open state. The purge gas supplied from the gas supply unit 216 thereby flows through the pipe 209b, the pipe 203b, the pipe 201b, the flow path 1112b, and the pipe 202b, and this flow of the purge gas causes the heat medium to return to the retaining unit 211b. The heat medium is thereby discharged from the flow path 1112b. As a result, the time taken for the temperature of the main body section 111 to stabilize is able to be shortened.

By using a control method similar to that described above, the controller 2 is able to switch the heat medium to be circulated to the main body section 111 from the heat medium at the first temperature to the heat medium at the second temperature. For example, the controller 2 controls the valve 221b to be in the open state and the valve 221a and the valve 223b to be in the closed state. Furthermore, in a case where the heat medium at the second temperature is caused to flow to the flow path 1112b, the controller 2 performs control so that a heat medium is discharged from the flow path 1112a. For example, the controller 2 controls the valve 223a to be in the open state.

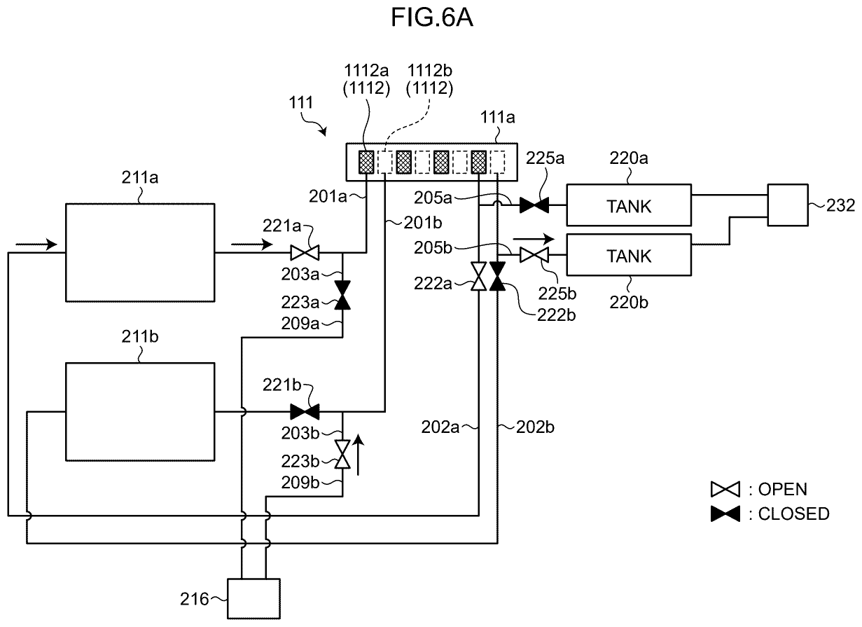

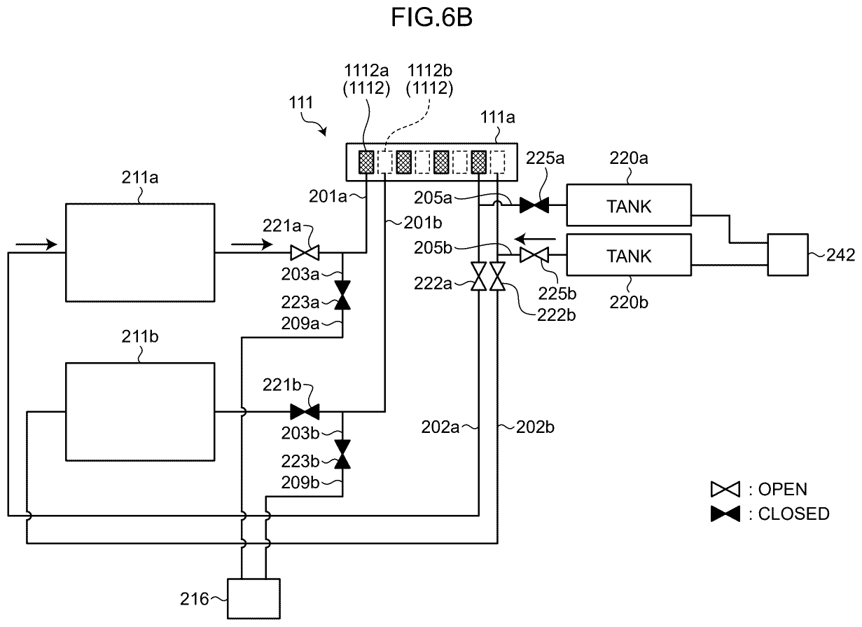

FIG. 6A and FIG. 6B are diagrams illustrating an example of another configuration of the temperature control device 200 according to the embodiment. The temperature control device 200 illustrated in FIG. 6A and FIG. 6B is partly the same as the temperature control devices 200 illustrated in FIG. 2 and FIG. 5, and the same reference sign will thus be assigned to portions that are the same, description of the same portions will be omitted, and portions that are different will be described mainly.

The pipes 202a and 202b illustrated in FIG. 6A and FIG. 6B are respectively provided with pipes 205a and 205b that branch off therefrom. The pipe 205a branches off from the pipe 202a at a position on one side of the valve 222a, the one side being toward the flow path 1112a. The pipe 205b branches off from the pipe 202b at a position on one side of the valve 222b, the one side being toward the flow path 1112b. The pipes 205a and 205b may hereinafter be collectively referred to as pipes 205. In the embodiment, the pipes 205 correspond to fifth pipes of the present disclosure.

The pipe 205a is provided with a valve 225a capable of opening and closing the pipe 205a. The pipe 205b is provided with a valve 225b capable of opening and closing the pipe 205b. The valves 225a and 225b may hereinafter be collectively referred to as valves 225. In the embodiment, the valves 225 correspond to fifth valves of the present disclosure.

The pipe 205a is connected to a tank 220a. The pipe 205b is connected to a tank 220b. The tanks 220a and 220b are each capable of retaining a heat medium. The tanks 220a and 220b may hereinafter be collectively referred to as tanks 220. In the embodiment, the tanks 220 correspond to second tanks of the present disclosure.

In a case where the heat medium at the first temperature is to be circulated to the main body section 111, the controller 2 controls the valve 221a and the valve 222a to be in the open state and controls the valve 221b, the valve 223a, and the valve 225a to be in the closed state. The heat medium at the first temperature thereby circulates through the retaining unit 211a and the flow path 1112a in the main body section 111 via the pipe 201a and the pipe 202a. Furthermore, in a case where the heat medium at the first temperature is caused to flow to the flow path 1112a, the controller 2 performs control so that a heat medium is discharged from the flow path 1112b. For example, as illustrated in FIG. 6A, the controller 2 controls the valve 223b and the valve 225b to be in the open state. The purge gas supplied from the gas supply unit 216 thereby flows through the pipe 209b, the pipe 203b, the pipe 201b, the flow path 1112b, the pipe 202b, and the pipe 205b, and this flow of the purge gas causes the heat medium to flow into the tank 220b. The heat medium is thereby discharged from the flow path 1112b. As a result, the time taken for the temperature of the main body section 111 to stabilize is able to be shortened.

In a case where a heat medium is to be discharged from the flow path 1112a or 1112b, the interior of the tank 220a or 220b may be depressurized. For example, as illustrated in FIG. 6A, an exhaust unit 232 to exhaust the interior of the tank 220a or 220b is connected to the tanks 220a and 220b. In the embodiment, the exhaust unit 232 corresponds to a second depressurizing unit of the present disclosure. In a case where the heat medium is to be discharged from the flow path 1112a, the controller 2 controls the exhaust unit 232 to exhaust the interior of the tank 220a by means of the exhaust unit 232 to depressurize the interior of the tank 220a. Furthermore, in a case where the heat medium is to be discharged from the flow path 1112b, the controller 2 controls the exhaust unit 232 to exhaust the interior of the tank 220b by means of the exhaust unit 232 to depressurize the interior of the tank 220b. The exhaust unit 232 may be the exhaust system 40, or an exhaust device provided separately from the exhaust system 40. In a case where the heat medium is to be discharged from the flow path 1112a or 1112b, depressurizing the interior of the tank 220a or 220b causes the heat medium in the flow path 1112a or 1112b to be sucked into the tank 220a or 220b and discharged quickly from the flow path 1112a or 1112b.

The heat medium retained in the tank 220b is able to be returned to the supply unit 210 by controlling as follows. For example, in a case where the heat medium retained in the tank 220b is to be returned to the retaining unit 211b, the controller 2 controls the valve 223b to be in the closed state and the valve 222b and the valve 225b to be in the open state, as illustrated in FIG. 6B. The heat medium retained in the tank 220b thereby flows into the retaining unit 211b via the pipe 205b and the pipe 202b.

The tanks 220a and 220b may be formed as a single tank 220. Furthermore, in a case where the heat medium retained in the tank 220a or 220b is caused to flow to the retaining unit 211a or 211b, the interior of the tank 220a or 220b may be pressurized. For example, as illustrated in FIG. 6B, a gas supply unit 242 to supply a purge gas is connected to the tanks 220a and 220b. In the embodiment, the gas supply unit 242 corresponds to a second pressurizing unit of the present disclosure. In a case where the heat medium retained in the tank 220a is caused to flow to the retaining unit 211a, the controller 2 controls the gas supply unit 242 to supply, for example, the purge gas to the tank 220a from the gas supply unit 242 and pressurize the interior of the tank 220a. In a case where the heat medium retained in the tank 220b is caused to flow to the retaining unit 211b, the controller 2 controls the gas supply unit 242 to supply, for example, the purge gas to the tank 220b from the gas supply unit 242 and pressurize the interior of the tank 220b. The gas supply unit 242 may be the gas supply unit 20 or a gas supply unit provided separately from the gas supply unit 20. Pressurizing the interior of the tank 220a or 220b causes the heat medium retained in the tank 220a or 220b to be pushed by pressure in the tank 220a or 220b and flow quickly into the retaining unit 211a or 211b. In a case where the controller 2 has finished returning the heat medium retained in the tank 220a to the retaining unit 211a, the controller 2 controls the valve 225a to be in the closed state, and in a case where the controller 2 has finished returning the heat medium retained in the tank 220b to the retaining unit 211b, the controller 2 controls the valve 225b to be in the closed state.

By using a control method similar to that described above, the controller 2 is able to switch the heat medium to be circulated to the main body section 111 from the heat medium at the first temperature to the heat medium at the second temperature. For example, the controller 2 controls the valve 221b and the valve 222b to be in the open state and controls the valve 221a, the valve 223b, and the valve 225b to be in the closed state. Furthermore, in a case where the heat medium at the second temperature is caused to flow to the flow path 1112b, the controller 2 performs control so that a heat medium is discharged from the flow path 1112a. For example, the controller 2 controls the valve 223a and the valve 225a to be in the open state. Furthermore, in a case where the heat medium retained in the tank 220a is to be returned to the retaining unit 211a, the controller 2 controls the valve 223a to be in the closed state and controls the valve 222a and the valve 225a to be in the open state.

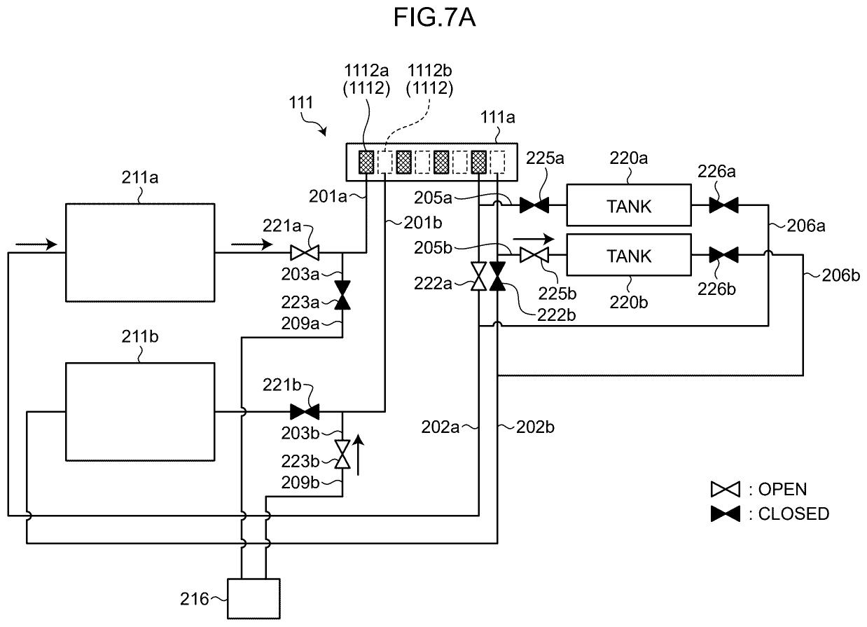

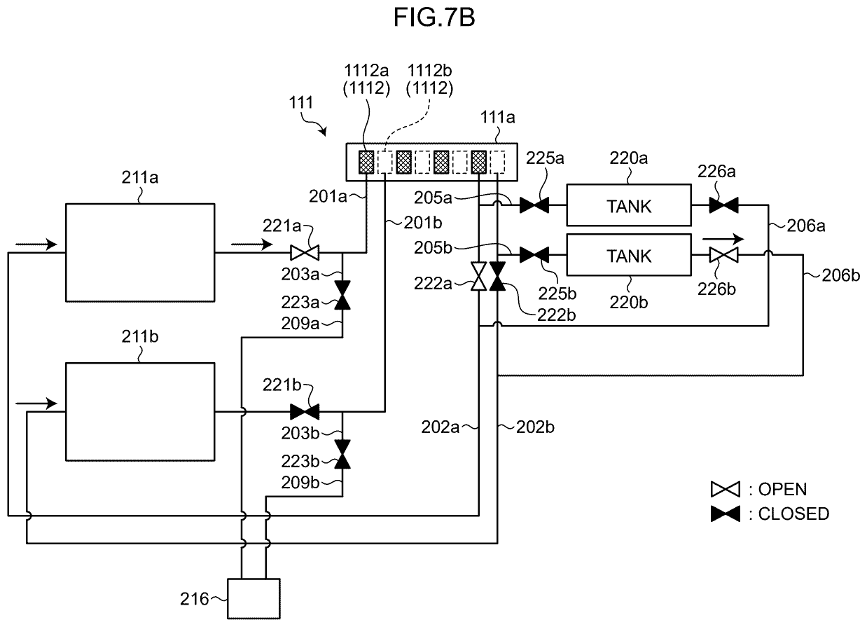

FIG. 7A and FIG. 7B are diagrams illustrating an example of another configuration of the temperature control device 200 according to the embodiment. The temperature control device 200 illustrated in FIG. 7A and FIG. 7B is partly the same as the temperature control device 200 illustrated in FIG. 6A and FIG. 6B, and the same reference sign will thus be assigned to portions that are the same, description of the same portions will be omitted, and portions that are different will be described mainly.

In the temperature control device 200 illustrated in FIG. 7A and FIG. 7B, a pipe 206a is connected to the tank 220a and a pipe 206b is connected to the tank 220b. The pipe 206a is provided with a valve 226a capable of opening and closing the pipe 206a. The pipe 206b is provided with a valve 226b capable of opening and closing the pipe 206b. The pipe 206a is connected to the pipe 202a on one side of the valve 222a of the pipe 202a, the one side being toward the retaining unit 211a. The pipe 206b is connected to the pipe 202b on one side of the valve 222b of the pipe 202b, the one side being toward the retaining unit 211b. Hereinafter, the pipes 206a and 206b may be collectively referred to as pipes 206 and the valves 226a and 226b may be collectively referred to as valves 226. In the embodiment, the pipes 206 correspond to sixth pipes of the present disclosure and the valves 226 correspond to sixth valves of the present disclosure.

In a case where the heat medium at the first temperature is to be circulated to the main body section 111, the controller 2 controls the valve 221a and the valve 222a to be in the open state and controls the valve 221b, the valve 223a, and the valve 225a to be in the closed state. The heat medium at the first temperature thereby circulates through the retaining unit 211a and the flow path 1112a in the main body section 111 via the pipe 201a and the pipe 202a. Furthermore, in a case where the heat medium at the first temperature is caused to flow to the flow path 1112a, the controller 2 performs control so that a heat medium is discharged from the flow path 1112b. For example, as illustrated in FIG. 7A, the controller 2 controls the valve 223b and the valve 225b to be in the open state and controls the valve 222b to be in the closed state. The purge gas supplied from the gas supply unit 216 thereby flows through the pipe 209b, the pipe 203b, the pipe 201b, the flow path 1112b, the pipe 202b, and the pipe 205b, and this flow of the purge gas causes the heat medium to flow into the tank 220b. As a result, the time taken for the temperature of the main body section 111 to stabilize is able to be shortened.

In a case where a heat medium is to be discharged from the flow path 1112a or 1112b, the interior of the tank 220a or 220b may be depressurized. For example, similarly to FIG. 6A, the exhaust unit 232 may be connected to the tanks 220a and 220b and the interior of the tank 220a or 220b may be exhausted by the exhaust unit 232.

The heat medium retained in the tank 220b is able to be returned to the supply unit 210 by controlling as follows. For example, in a case where the heat medium retained in the tank 220b is to be returned to the retaining unit 211b, the controller 2 controls the valve 223b, the valve 222b, and the valve 225b to be in the closed state and controls the valve 226b to be in the open state, as illustrated in FIG. 7B. The heat medium retained in the tank 220b thereby flows into the retaining unit 211b via the pipe 206b and the pipe 202b.

The tanks 220a and 220b may be formed as a single tank 220. Furthermore, in a case where the heat medium retained in the tank 220a or 220b is caused to flow to the retaining unit 211a or 211b, the interior of the tank 220a or 220b may be pressurized. For example, similarly to FIG. 6B, the gas supply unit 242 may be connected to the tanks 220a and 220b, and the interior of the tank 220a or 220b may be pressurized by the gas supply unit 242.

By using a control method similar to that described above, the controller 2 is able to switch the heat medium to be circulated to the main body section 111 from the heat medium at the first temperature to the heat medium at the second temperature. For example, the controller 2 controls the valve 221b and the valve 222b to be in the open state and controls the valve 221a, the valve 223b, and the valve 225b to be in the closed state. Furthermore, in a case where the heat medium at the second temperature is caused to flow to the flow path 1112b, the controller 2 performs control so that a heat medium is discharged from the flow path 1112a. For example, the controller 2 controls the valve 223a and the valve 225a to be in the open state and controls the valve 222a to be in the closed state. Furthermore, in a case where the heat medium retained in the tank 220a is to be returned to the retaining unit 211a, the controller 2 controls the valve 223a, the valve 222a, and the valve 225a to be in the closed state and controls the valve 226a to be in the open state.

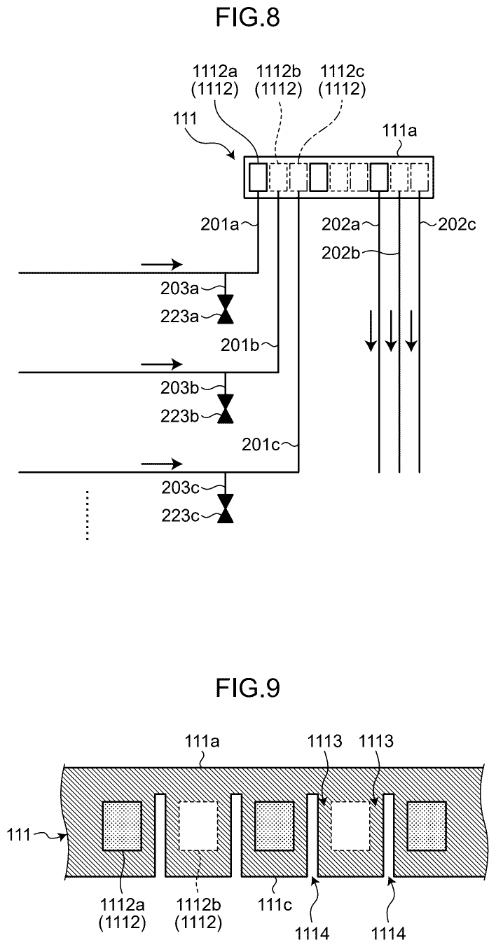

In the case described as an example with respect to the above described embodiment, the temperature control device 200 switches between and causes flow of heat media at two different temperatures. However, techniques disclosed herein are not to be limited to this example. The temperature control device 200 may be configured to switch between and cause flow of heat media at three or more different temperatures. FIG. 8 is a diagram schematically illustrating another example of the configuration of the main body section 111. FIG. 8 illustrates the configuration of the main body section 111 in a simplified manner. Three flow paths (1112a, 1112b, and 1112c) are formed inside the main body section 111 illustrated in FIG. 8. The flow paths 1112a, 1112b, and 1112c are formed to not intersect with one another below the central area 111a. The pipe 201a is connected to one end of the flow path 1112a and the pipe 202a is connected to the other end of the flow path 1112a. The pipe 201b is connected to one end of the flow path 1112b and the pipe 202b is connected to the other end of the flow path 1112b. A pipe 201c is connected to one end of the flow path 1112c and a pipe 202c is connected to the other end of the flow path 1112c. The pipes 202a, 202b, and 202c are respectively provided with the pipes 203a and 203b and a pipe 203c that branch off therefrom. The pipe 203a is provided with the valve 223a capable of opening and closing the pipe 203a. The pipe 203b is provided with the valve 223b capable of opening and closing the pipe 203b. The pipe 203c is provided with a valve 223c capable of opening and closing the pipe 203c. The main body section 111 having the configuration illustrated in FIG. 8 allows three heat media to flow therethrough. By being configured correspondingly to the one flow path added to allow the three heat media to flow, the temperature control device 200 mentioned above is able to switch between and cause flow of the heat media at three different temperatures to the flow paths 1112a, 1112b, and 1112c in the main body section 111 illustrated in FIG. 8.

Furthermore, the main body section 111 may be configured so that heat transfer between the plurality of flow paths 1112 is reduced. For example, the main body section 111 may be configured so that heat transfer is reduced by providing, in partition wall portions between the plurality of flow paths 1112, portions having higher thermal resistance than the surroundings. FIG. 9 is a diagram illustrating an example of the configuration of the main body section 111 according to the embodiment. The flow paths 1112a and 1112b have been formed in the main body section 111 illustrated in FIG. 9. The flow paths 1112a and 1112b are formed in parallel and partition walls 1113 are respectively provided between the flow paths 1112a and 1112b. Slits 1114 are respectively provided in the partition walls 1113, the slits 1114 serving as portions having higher thermal resistance than the surroundings. The slits 1114 pass between the flow paths 1112a and 1112b from the direction of a reverse face 111c opposite to the central area 111a of the main body section 111 and reaches positions that are more toward the central area 111a than the flow paths 1112a and 1112b. Providing the slits 1114 respectively between the flow paths 1112a and 1112b reduces the heat transfer between the flow paths 1112a and 1112b in the main body section 111 and enables reduction of transfer of heat between the heat media in the flow paths 1112a and 1112b.

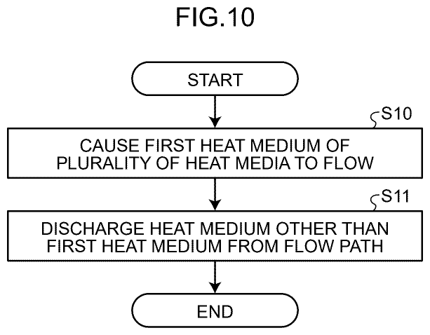

A processing flow of a temperature control method according to the embodiment will be described next. FIG. 10 is a flowchart illustrating an example of the processing flow of the temperature control method according to the embodiment. Processing in the temperature control method according to the embodiment is executed when the heat medium circulated to the main body section 111 is to be switched.

The controller 2 performs control to cause the first heat medium, among the plurality of heat media, to flow from the supply unit 210 into a flow path 1112 of the main body section 111 having, formed therein, the plurality of flow paths 1112 that respectively allow the plurality of heat media to separately flow therethrough (Step S10). For example, the controller 2 performs control to cause the heat medium at the first temperature to flow from the supply unit 210 into the flow path 1112a formed in the main body section 111.

In a case where the first heat medium is caused to flow through a flow path 1112, the controller 2 performs control to discharge a heat medium of the plurality of heat media and other than the first heat medium, from a flow path 1112 (Step S11) and ends the processing. For example, the controller 2 performs control to discharge the heat medium from the flow path 1112b formed in the main body section 111.

In the case described as an example with respect to the above described embodiment, the plurality of flow paths 1112 are formed as a component included in the plasma processing apparatus 1, in the main body section 111 where the substrate W is placed, the heat media caused to flow to the respective flow paths 1112 are controlled, and the temperature of the main body section 111 is thereby controlled. However, the techniques disclosed herein are not to be limited to this example. For example, a plurality of flow paths may be formed in another component, such as the plasma processing chamber 10 or the shower head 13, of the plasma processing apparatus 1, and the temperature of that other component may be controlled by controlling heat media caused to flow to the respective flow paths. The disclosed techniques enable, by forming a plurality of flow paths in a target member to be subjected to temperature control and controlling heat media caused to flow to the respective flow paths, control of temperature of the target member.

Furthermore, in the case described as an example with respect to the above described embodiment, the substrate processing apparatus is the plasma processing apparatus 1 for processing the substrate W by using plasma. However, the techniques disclosed herein are not to be limited to this example. The disclosed techniques are applicable to any other apparatus for processing a substrate W even if the apparatus is a processing apparatus that does not use plasma.

Furthermore, the plasma processing apparatus 1 for performing processing using capacitively coupled plasma (CCP) as an example of a plasma source has been described with respect to the above described embodiment, but the plasma source is not limited to this example. Plasma sources other than capacitively coupled plasma may be, for example, inductively coupled plasma (ICP), microwave-excited surface-wave plasma (SWP), electron cyclotron resonance plasma (ECP), and helicon-wave-excited plasma (HWP).

Furthermore, in the case described as an example with respect to the above described embodiment, the controller 2 of the plasma processing apparatus 1 controls the temperature control device 200. However, the techniques disclosed herein are not to be limited to this example. The temperature control device 200 may have a controller that controls the temperature control device 200, separately from the controller 2.

Embodiments have been described above. As described above, the plasma processing system according to the above described embodiment has the supply unit 210 (heat medium supply unit), the main body section 111 (component), and the controller 2. The supply unit 210 is configured to be capable of supplying each of a plurality of heat media each having a different temperature. The main body section 111 is included in the plasma processing system and has the plurality of flow paths 1112 formed therein, the plurality of flow paths 1112 respectively allowing the plurality of heat media to separately flow therethrough. The controller 2 is configured to perform control so that in a case where the first heat medium of the plurality of heat media is caused to flow to a flow path 1112 from the supply unit 210, a heat medium of the plurality of heat media and other than the first heat medium is discharged from a flow path 1112. The plasma processing system according to the embodiment thereby enables time for temperature of the main body section 111 to stabilize to be shortened.

Furthermore, the plasma processing system according to the above described embodiment further has the plurality of pipes 201 (first pipes), the plurality of pipes 202 (second pipes), the plurality of valves 221 (first valves), the plurality of pipes 203 (third pipes), and the plurality of valves 223 (second valves). The plurality of pipes 201 respectively connect one end of the plurality of flow paths 1112 in the main body section 111 and the supply unit 210 to each other and transport the plurality of heat media supplied from the supply unit 210 to the plurality of flow paths 1112. The plurality of pipes 202 respectively connect the other end of the plurality of flow paths 1112 in the main body section 111 and the supply unit 210 to each other and transport the heat media discharged from the plurality of flow paths 1112 to the supply unit 210. The plurality of valves 221 are respectively provided in the plurality of pipes 201 and are capable of respectively opening and closing the plurality of pipes 201. The plurality of pipes 203 respectively branch off from the plurality of pipes 201 and respectively branch off from positions on one side of the valves 221 in the pipes 201, the one side being toward the flow paths 1112. The plurality of valves 223 are respectively provided in the plurality of pipes 203 and are capable of respectively opening and closing the plurality of pipes 203. The controller 2 is configured so that in a case where the first heat medium is caused to flow to a flow path 1112, the controller 2 controls the valve 221 in the pipe 201 that transports the first heat medium, to be in the open state, controls the valve 221 in the pipe 201 that transports a heat medium other than the first heat medium, to be in the closed state, and controls the valve 223 in the pipe 203 that branches off from the pipe 201 that transports the heat medium other than the first heat medium, to be in the open state. The plasma processing system according to the embodiment enables a heat medium of the plurality of heat media and other than the first heat medium to be discharged from a flow path 1112, in a case where the first heat medium of the plurality of heat media is caused to flow to a flow path 1112 from the supply unit 210. The plasma processing system according to the embodiment thereby enables the time for the temperature of the main body section 111 to stabilize to be shortened.

Furthermore, the plasma processing system according to the embodiment described above further has the tank 212 (first tank). The tank 212 is arranged at a position lower than that of the main body section 111, is connected to the plurality of pipes 203, and is capable of retaining a heat medium. The plasma processing system according to the embodiment thereby enables flow of a heat medium that is retained in a flow path 1112 and is other than the first heat medium to the tank 212 under the action of gravity without using a pump, for example. Furthermore, the plasma processing system according to the embodiment enables the heat medium that is discharged and is other than the first heat medium to be retained in the tank 212.

Furthermore, the plasma processing system according to the above described embodiment further has the exhaust unit 231 (first depressurizing unit). The exhaust unit 231 is configured to be capable of depressurizing the interior of the tank 212. The controller 2 is configured to depressurize the interior of the tank 212 by means of the exhaust unit 231 and control the valve 223 in the pipe 203 to be in the open state, the pipe 203 branching off from the pipe 201 that transports the heat medium other than the first heat medium. In the plasma processing system according to the embodiment, the heat medium in a flow path 1112 is thereby sucked into the tank 212 and quickly discharged from the flow path 1112.

Furthermore, the plasma processing system according to the above described embodiment further has the plurality of pipes 204 (fourth pipes) and the plurality of valves 224 (third valves). The plurality of pipes 204 connect the tank 212 and the plurality of pipes 202 to each other. The plurality of valves 224 are respectively provided in the plurality of pipes 204 and are capable of respectively opening and closing the plurality of pipes 204. The controller 2 is configured so that in a case where the heat medium retained in the tank 212 is to be returned to the supply unit 210, the controller 2 controls the valve 224 in the pipe 204 to be in the open state, the pipe 204 being connected to the pipe 202 that transports the heat medium other than the first heat medium to the supply unit 210. The plasma processing system according to the embodiment thereby enables the heat medium retained in the tank 212 to be returned to the supply unit 210.

Furthermore, the plasma processing system according to the above described embodiment further has the gas supply unit 241 (first pressurizing unit). The gas supply unit 241 is configured to be capable of pressurizing the interior of the tank 212. The controller 2 is configured to pressurize the interior of the tank 212 by means of the gas supply unit 241 and control the valve 224 in the pipe 204 to be in the open state, the pipe 204 being connected to the pipe 202 that transports the heat medium other than the first heat medium to the supply unit 210, in the case where the heat medium retained in the tank 212 is to be returned to the supply unit 210. The plasma processing system according to the embodiment thereby enables the heat medium retained in the tank 212 to be quickly returned to the supply unit 210.

Furthermore, the plasma processing system according to the above described embodiment further has the gas supply unit 216. The gas supply unit 216 is connected to the plurality of pipes 203 and is configured to be capable of supplying a purge gas to the plurality of pipes 203. The controller 2 is configured to control, in a case where the first heat medium is caused to flow to a flow path 1112, the gas supply unit 216 to supply the purge gas to the pipe 203 that branches off from the pipe 201 that transports the heat medium other than the first heat medium. The plasma processing system according to the embodiment thereby enables the heat medium of the plurality of heat media and other than the first heat medium to be quickly discharged from a flow path 1112, in a case where the first heat medium of the plurality of heat media is caused to flow to a flow path 1112 from the supply unit 210.

Furthermore, the plasma processing system according to the above described embodiment further has the plurality of valves 222 (fourth valves), the plurality of pipes 205 (fifth pipes), the plurality of valves 225 (fifth valves), and the tank 220 (second tank). The plurality of valves 222 are respectively provided in the plurality of pipes 202 and are capable of respectively opening and closing the plurality of pipes 202. The plurality of pipes 205 respectively branch off from the plurality of pipes 202 and respectively branch off from positions on one side of the valves 222 in the pipes 202, the one side being toward the flow paths 1112. The plurality of valves 225 are respectively provided in the plurality of pipes 205 and are capable of respectively opening and closing the plurality of pipes 205. The tank 220 is connected to the plurality of pipes 205 and is capable of retaining a heat medium. The controller 2 is configured so that in a case where the first heat medium is caused to flow to a flow path 1112, the controller 2 controls the valve 222 in the pipe 202 that transports the first heat medium, to be in the open state, controls the valve 222 in the pipe 202 that transports the heat medium other than the first heat medium, to be in the closed state, controls the valve 225 in the pipe 205 that branches off from the pipe 202 that transports the first heat medium, to be in the closed state, and controls the valve 225 in the pipe 205 that branches off from the pipe 202 that transports the heat medium other than the first heat medium, to be in the open state. The plasma processing system according to the embodiment thereby enables flow of the heat medium that is retained in a flow path 1112 and is other than the first heat medium, to the tank 220. Furthermore, the plasma processing system according to the embodiment enables the heat medium that is discharged and is other than the first heat medium to be retained in the tank 220.

Furthermore, the plasma processing system according to the above described embodiment further has the exhaust unit 232 (second depressurizing unit). The exhaust unit 232 is configured to be capable of depressurizing the interior of the tank 220. The controller 2 is configured to depressurize the interior of the tank 220 by means of the exhaust unit 232 and control the valve 225 in the pipe 205 to be in the open state, the pipe 205 branching off from the pipe 202 that transports the heat medium other than the first heat medium. In the plasma processing system according to the embodiment, the heat medium in the flow path 1112 is thereby sucked into the tank 220 and quickly discharged from the flow path 1112.

Furthermore, the plasma processing system according to the above described embodiment further has the plurality of pipes 206 (sixth pipes) and the plurality of valves 226 (sixth valves). The plurality of pipes 206 connect the tank 220 and the plurality of pipes 202 to each other and are respectively connected to the plurality of pipes 202 on one side of the valves 222, the one side being toward the supply unit 210. The plurality of valves 226 are respectively provided in the plurality of pipes 206 and are capable of respectively opening and closing the plurality of pipes 206. The controller 2 is configured so that in a case where the heat medium retained in the tank 220 is to be returned to the supply unit 210, the controller 2 controls the valve 226 in the pipe 206 to be in the open state, the pipe 206 being connected to the pipe 202 that transports the heat medium other than the first heat medium to the supply unit 210. The plasma processing system according to the embodiment thereby enables the heat medium retained in the tank 220 to be returned to the supply unit 210.

Furthermore, the plasma processing system according to the above described embodiment further has the gas supply unit 242 (second pressurizing unit). The gas supply unit 242 is configured to be capable of pressurizing the interior of the tank 220. The controller 2 is configured to pressurize the interior of the tank 220 by means of the gas supply unit 242 and control the valve 226 in the pipe 206 to be in the open state, the pipe 206 being connected to the pipe 202 that transports the heat medium other than the first heat medium to the supply unit 210, in the case where the heat medium retained in the tank 220 is to be returned to the supply unit 210. The plasma processing system according to the embodiment thereby enables the heat medium retained in the tank 220 to be quickly returned to the supply unit 210.

Furthermore, the main body section 111 is configured so that heat transfer between the plurality of flow paths 1112 is reduced. The main body section 111 enables reduction of heat transfer between heat media in the flow paths 1112.

The embodiments disclosed herein are exemplary in all respects and are not to be construed as limiting. Indeed, the above described embodiments can be embodied in various forms. Furthermore, various omissions, replacements, and modifications can be made to the above described embodiments without departing from the scope and spirit of the appended claims.

According to the present disclosure, time for temperature of a component to stabilize is able to be shortened.

Although the disclosure has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

With respect to the above described embodiments, the following notes are additionally disclosed.

### Note 1

A substrate processing apparatus, comprising:
a heat medium supply supplying each of a plurality of heat media, the plurality of heat media having a different temperatures from one another;
a component included in the substrate processing apparatus and having a plurality of flow paths formed in the component, the plurality of flow paths respectively allowing the plurality of heat media to separately flow through the plurality of flow paths; and
controller circuitry configured to, when a first heat medium of the plurality of heat media is caused to flow to the plurality of flow paths from the heat medium supply, cause a second heat medium of the plurality of heat media and other than the first heat medium to be discharged from the plurality of flow paths.

### Note 2

The substrate processing apparatus according to note 1, further comprising:
a plurality of first pipes that respectively connect one end of the plurality of flow paths in the component and the heat medium supply to each other and transport the plurality of heat media supplied from the heat medium supply to the plurality of flow paths;
a plurality of second pipes that respectively connect the other end of the plurality of flow paths in the component and the heat medium supply to each other and transport a heat medium among the plurality of heat media discharged from the plurality of flow paths to the heat medium supply;
a plurality of first valves respectively provided in the plurality of first pipes and capable of respectively opening and closing the plurality of first pipes;
a plurality of third pipes that respectively branch off from the plurality of first pipes and respectively branch off from positions on one side off the first valves in the first pipes, the one side being toward the plurality of flow paths; and
a plurality of second valves respectively provided in the plurality of third pipes and capable of respectively opening and closing the plurality of third pipes, wherein
the controller circuitry is configured to, when the first heat medium is caused to flow to the plurality of flow paths, control the first valve in the first pipe that transports the first heat medium, to be in an open state, control the first valve in the first pipe that transports the second heat medium to be in a closed state, and control the second valve in the third pipe that branches off from the first pipe that transports the second heat medium to be in the open state.

### Note 3

The substrate processing apparatus according to note 2, further comprising:
a first tank arranged at a position lower than that of the component, connected to the plurality of third pipes, and capable of retaining a heat medium.

### Note 4

The substrate processing apparatus according to note 3, further comprising:
a first exhaust configured to be capable of depressurizing the interior of the first tank, wherein
the controller circuitry is configured to control the first exhaust to depressurize the interior of the first tank and control the second valve in the third pipe to be in the open state, the third pipe branching off from the first pipe that transports the second heat medium.

### Note 5

The substrate processing apparatus according to note 3 or 4, further comprising:
a plurality of fourth pipes that connect the first tank and the plurality of second pipes to each other; and
a plurality of third valves respectively provided in the plurality of fourth pipes and capable of respectively opening and closing the plurality of fourth pipes, wherein
the controller circuitry is configured to, when the heat medium retained in the first tank is to be returned to the heat medium supply, control the third valve in the fourth pipe to be in the open state, the fourth pipe being connected to the second pipe that transports the second heat medium to the heat medium supply.

### Note 6

The substrate processing apparatus according to note 5, further comprising:
a first gas supply pressurizing the interior of the first tank, wherein
the controller circuitry is configured to control the first gas supply to pressurize the interior of the first tank and control the third valve in the fourth pipe to be in the open state, the fourth pipe being connected to the second pipe that transports the second heat medium to the heat medium supply,
when the heat medium retained in the first tank is to be returned to the heat medium supply.

### Note 7

The substrate processing apparatus according to note 2, further comprising:
a gas supply connected to the plurality of third pipes and supplying a purge gas to the plurality of third pipes, wherein
the controller circuitry is configured to control, when the first heat medium is caused to flow to the plurality of flow paths, the gas supply to supply the purge gas to the third pipe that branches off from the first pipe that transports the second heat medium.

### Note 8

The substrate processing apparatus according to note 7, further comprising:
a plurality of fourth valves respectively provided in the plurality of second pipes and capable of respectively opening and closing the plurality of second pipes;
a plurality of fifth pipes that respectively branch off from the plurality of second pipes and respectively branch off from positions on one side of the fourth valves in the second pipes, the one side being toward the plurality of flow paths;
a plurality of fifth valves respectively provided in the plurality of fifth pipes and capable of respectively opening and closing the plurality of fifth pipes; and
a second tank connected to the plurality of fifth pipes and capable of retaining a heat medium, wherein
the controller circuitry is configured to, when the first heat medium is caused to flow to the plurality of flow paths, control the fourth valve in the second pipe that transports the first heat medium, to be in the open state, control the fourth valve in the second pipe that transports the second heat medium to be in the closed state, control the fifth valve in the fifth pipe that branches off from the second pipe that transports the first heat medium, to be in the closed state, and control the fifth valve in the fifth pipe that branches off from the second pipe that transports the second heat medium to be in the open state.

### Note 9

The substrate processing apparatus according to note 8, further comprising:
a second exhaust depressurizing the interior of the second tank, wherein
the controller circuitry is configured to control the second exhaust depressurize the interior of the second tank and control the fifth valve in the fifth pipe to be in the open state, the fifth pipe branching off from the second pipe that transports the second heat medium.

### Note 10

The substrate processing apparatus according to note 8 or 9, further comprising:
a plurality of sixth pipes that connect the second tank and the plurality of second pipes to each other and are respectively connected to the plurality of second pipes on one side of the fourth valves, the one side being toward the heat medium supply; and
a plurality of sixth valves respectively provided in the plurality of sixth pipes and capable of respectively opening and closing the plurality of sixth pipes, wherein
the controller circuitry is configured to, when the heat medium retained in the second tank is to be returned to the heat medium supply, control the sixth valve in the sixth pipe to be in the open state, the sixth pipe being connected to the second pipe that transports the second heat medium to the heat medium supply.

### Note 11

The substrate processing apparatus according to note 10, further comprising:
a second gas supply pressurizing the interior of the second tank, wherein
the controller circuitry is configured to control the second gas supply to pressurize the interior of the second tank and control the sixth valve in the sixth pipe to be in the open state, the sixth pipe being connected to the second pipe that transports the second heat medium to the heat medium supply, when the heat medium retained in the second tank is to be returned to the heat medium supply.

### Note 12

The substrate processing apparatus according to any one of notes 1 to 11, wherein the component is configured so that heat transfer between the plurality of flow paths is reduced.

### Note 13

The substrate processing apparatus according to any one of notes 1 to 11, wherein the component is a stage having a placing surface where a substrate is to be placed and the plurality of flow paths are formed in an area below the placing surface.

### Note 14

A temperature control device, comprising:
a heat medium supply supplying each of a plurality of heat media, the plurality of heat media having different temperatures from one another; and
controller circuitry configured to perform control, when a first heat medium of the plurality of heat media is caused to flow from the heat medium supply to a plurality of flow paths that are formed in a target member to be subjected to temperature control, are individually connected to the heat medium supply, and respectively allow the plurality of heat media to separately flow therethrough, a second heat medium of the plurality of heat media and other than the first heat medium is discharged from the plurality of flow paths.

### Note 15

A temperature control method, including:
a process of causing a first heat medium of a plurality of heat media, the plurality of heat media having different temperatures from one another, to flow from a heat medium supply configured to be capable of supplying each of the plurality of heat media, to a plurality of flow paths formed in a component included in a substrate processing apparatus, the plurality of flow paths being individually connected to the heat medium supply and respectively allowing the plurality of heat media to separately flow therethrough; and
a process of causing, when the first heat medium is caused to flow to the plurality of flow paths, a second heat medium of the plurality of heat media and other than the first heat medium is discharged from the plurality of flow paths.

### Note 16

The temperature control device according to note 14, further comprising:
a plurality of first pipes that respectively connect one end of the plurality of flow paths in the target member and the heat medium supply to each other and transport the plurality of heat media supplied from the heat medium supply to the plurality of flow paths;
a plurality of second pipes that respectively connect an other end of the plurality of flow paths in the target member and the heat medium supply to each other and transport a heat medium discharged from the plurality of flow paths to the heat medium supply;
a plurality of first valves respectively provided in the plurality of first pipes and capable of respectively opening and closing the plurality of first pipes; and
a plurality of third pipes that respectively branch off from the plurality of first pipes at positions on one side of the first valves in the first pipes, the one side being toward the plurality of flow paths,
wherein the controller circuitry is configured to, when the first heat medium is caused to flow to the plurality of flow paths, control the first valve in the first pipe that transports the first heat medium to be in an open state, control the first valve in the first pipe that transports the second heat medium to be in a closed state, and control a second valve in the third pipe that branches off from the first pipe that transports the second heat medium to be in an open state.

### Note 17

The temperature control device according to note 16, further comprising:
a first tank arranged at a position lower than that of the target member, connected to the plurality of third pipes, and capable of retaining a heat medium; and
a first exhaust depressurizing an interior of the first tank,
wherein the controller circuitry is configured to control the first exhaust to depressurize the interior of the first tank and control the second valve in the third pipe to be in the open state, the third pipe branching off from the first pipe that transports the second heat medium.

### Note 18

The temperature control device according to note 16, further comprising:
a gas supply connected to the plurality of third pipes and supplying a purge gas to the plurality of third pipes,
wherein the controller circuitry is configured to control, when the first heat medium is caused to flow to the plurality of flow paths, the gas supply to supply the purge gas to the third pipe that branches off from the first pipe that transports the second heat medium other than the first heat medium.

### Note 19

The temperature control method according to note 15, further comprising:
a process of depressurizing an interior of a first tank connected to a plurality of third pipes that respectively branch off from a plurality of first pipes at positions on one side of first valves in the first pipes, the one side being toward the plurality of flow paths, and the first pipes respectively connecting one end of the plurality of flow paths and the heat medium supply to each other,
wherein the process of causing the second heat medium to be discharged comprises causing the second heat medium to be sucked into the first tank by the depressurizing of the interior of the first tank.

### Note 20

The temperature control method according to note 15, further comprising:
a process of supplying a purge gas from a gas supply to a third pipe that branches off from a first pipe that transports the second heat medium other than the first heat medium, the first pipe connecting one end of a flow path in the component and the heat medium supply to each other,
wherein the process of causing the second heat medium to be discharged comprises causing the second heat medium to flow out of the flow path by the supplying of the purge gas.

What is claimed is:

1. A substrate processing apparatus, comprising:
a heat medium supply supplying each of a plurality of heat media, the plurality of heat media having different temperatures from one another;
a component included in the substrate processing apparatus and having a plurality of flow paths formed in the component, the plurality of flow paths respectively allowing the plurality of heat media to separately flow through the plurality of flow paths; and
controller circuitry configured to, when a first heat medium of the plurality of heat media is caused to flow to the plurality of flow paths from the heat medium supply, cause a second heat medium of the plurality of heat media and other than the first heat medium to be discharged from the plurality of flow paths.

2. The substrate processing apparatus according to claim 1, further comprising:
a plurality of first pipes that respectively connect one end of the plurality of flow paths in the component and the heat medium supply to each other and transport the plurality of heat media supplied from the heat medium supply to the plurality of flow paths;
a plurality of second pipes that respectively connect an other end of the plurality of flow paths in the component and the heat medium supply to each other and transport a heat medium among the plurality of heat media discharged from the plurality of flow paths to the heat medium supply;
a plurality of first valves respectively provided in the plurality of first pipes and capable of respectively opening and closing the plurality of first pipes;
a plurality of third pipes that respectively branch off from the plurality of first pipes and respectively branch off from positions on one side off the first valves in the first pipes, the one side being toward the plurality of flow paths; and
a plurality of second valves respectively provided in the plurality of third pipes and capable of respectively opening and closing the plurality of third pipes, wherein
the controller circuitry is configured to, when the first heat medium is caused to flow to the plurality of flow paths, control the first valve in the first pipe that transports the first heat medium, to be in an open state, control the first valve in the first pipe that transports the second heat medium, to be in a closed state, and control the second valve in the third pipe that branches off from the first pipe that transports the second heat medium, to be in the open state.

3. The substrate processing apparatus according to claim 2, further comprising:
a first tank arranged at a position lower than that of the component, connected to the plurality of third pipes, and capable of retaining a heat medium.

4. The substrate processing apparatus according to claim 3, further comprising:
a first exhaust depressurizing the interior of the first tank, wherein
the controller circuitry is configured to control the first exhaust to depressurize the interior of the first tank and control the second valve in the third pipe to be in the open state, the third pipe branching off from the first pipe that transports the second heat medium.

5. The substrate processing apparatus according to claim 3, further comprising:
a plurality of fourth pipes that connect the first tank and the plurality of second pipes to each other; and
a plurality of third valves respectively provided in the plurality of fourth pipes and capable of respectively opening and closing the plurality of fourth pipes, wherein
the controller circuitry is configured to, when the heat medium retained in the first tank is to be returned to the heat medium supply, control the third valve in the fourth pipe to be in the open state, the fourth pipe being connected to the second pipe that transports the second heat medium to the heat medium supply.

6. The substrate processing apparatus according to claim 5, further comprising:
a first gas supply pressurizing the interior of the first tank, wherein
the controller circuitry is configured to control the first gas supply to pressurize the interior of the first tank and control the third valve in the fourth pipe to be in the open state, the fourth pipe being connected to the second pipe that transports the second heat medium to the heat medium supply, when the heat medium retained in the first tank is to be returned to the heat medium supply.

7. The substrate processing apparatus according to claim 2, further comprising:
a gas supply connected to the plurality of third pipes and supplying a purge gas to the plurality of third pipes, wherein
the controller circuitry is configured to control, when the first heat medium is caused to flow to the plurality of flow paths, the gas supply to supply the purge gas to the third pipe that branches off from the first pipe that transports the second heat medium.

8. The substrate processing apparatus according to claim 7, further comprising:
a plurality of fourth valves respectively provided in the plurality of second pipes and capable of respectively opening and closing the plurality of second pipes;
a plurality of fifth pipes that respectively branch off from the plurality of second pipes and respectively branch off from positions on one side of the fourth valves in the second pipes, the one side being toward the plurality of flow paths;
a plurality of fifth valves respectively provided in the plurality of fifth pipes and capable of respectively opening and closing the plurality of fifth pipes; and
a second tank connected to the plurality of fifth pipes and capable of retaining a heat medium, wherein
the controller circuitry is configured to, when the first heat medium is caused to flow to the plurality of flow paths control the fourth valve in the second pipe that transports the first heat medium, to be in the open state, control the fourth valve in the second pipe that transports the second heat medium other than the first heat medium, to be in the closed state, control the fifth valve in the fifth pipe that branches off from the second pipe that transports the first heat medium, to be in the closed state, and control the fifth valve in the fifth pipe that branches off from the second pipe that transports the second heat medium to be in the open state.

9. The substrate processing apparatus according to claim 8, further comprising:
a second exhaust depressurizing the interior of the second tank, wherein
the controller circuitry is configured to control the second exhaust to depressurize the interior of the second tank and control the fifth valve in the fifth pipe to be in the open state, the fifth pipe branching off from the second pipe that transports the second heat medium.

10. The substrate processing apparatus according to claim 8, further comprising:
a plurality of sixth pipes that connect the second tank and the plurality of second pipes to each other and are respectively connected to the plurality of second pipes on one side of the fourth valves, the one side being toward the heat medium supply; and
a plurality of sixth valves respectively provided in the plurality of sixth pipes and capable of respectively opening and closing the plurality of sixth pipes, wherein
the controller circuitry is configured to, when the heat medium retained in the second tank is to be returned to the heat medium supply, control the sixth valve in the sixth pipe to be in the open state, the sixth pipe being connected to the second pipe that transports the second heat medium to the heat medium supply.

11. The substrate processing apparatus according to claim 10, further comprising:
a second gas supply pressurizing the interior of the second tank, wherein
the controller circuitry is configured to control the second gas supply to pressurize the interior of the second tank and control the sixth valve in the sixth pipe to be in the open state, the sixth pipe being connected to the second pipe that transports the second heat medium to the heat medium supply, when the heat medium retained in the second tank is to be returned to the heat medium supply.

12. The substrate processing apparatus according to claim 1, wherein the component is configured so that heat transfer between the plurality of flow paths is reduced.

13. The substrate processing apparatus according to claim 1, wherein the component is a stage having a placing surface where a substrate is to be placed and the plurality of flow paths are formed in an area below the placing surface.

14. A temperature control device, comprising:
a heat medium supply supplying each of a plurality of heat media, the plurality of heat media having different temperatures from one another; and
controller circuitry configured to perform control, when a first heat medium of the plurality of heat media is caused to flow from the heat medium supply to a plurality of flow paths that are formed in a target member to be subjected to temperature control, are individually connected to the heat medium supply, and respectively allow the plurality of heat media to separately flow therethrough, a second heat medium of the plurality of heat media and other than the first heat medium is discharged from the plurality of flow paths.

15. A temperature control method, including:
a process of causing a first heat medium of a plurality of heat media, the plurality of heat media different temperatures from one another, to flow from a heat medium supply supplying each of the plurality of heat media, to a plurality of flow paths formed in a component included in a substrate processing apparatus, the plurality of flow paths being individually connected to the heat medium supply and respectively allowing the plurality of heat media to separately flow therethrough; and
a process of causing, when the first heat medium is caused to flow to the plurality of flow paths, a second heat medium of the plurality of heat media and other than the first heat medium to be discharged from the plurality of flow paths.

16. The temperature control device according to claim 14, further comprising:
a plurality of first pipes that respectively connect one end of the plurality of flow paths in the target member and the heat medium supply to each other and transport the plurality of heat media supplied from the heat medium supply to the plurality of flow paths;
a plurality of second pipes that respectively connect an other end of the plurality of flow paths in the target member and the heat medium supply to each other and transport a heat medium discharged from the plurality of flow paths to the heat medium supply;
a plurality of first valves respectively provided in the plurality of first pipes and capable of respectively opening and closing the plurality of first pipes; and
a plurality of third pipes that respectively branch off from the plurality of first pipes at positions on one side of the first valves in the first pipes, the one side being toward the plurality of flow paths,
wherein the controller circuitry is configured to, when the first heat medium is caused to flow to the plurality of flow paths, control the first valve in the first pipe that transports the first heat medium to be in an open state, control the first valve in the first pipe that transports the second heat medium to be in a closed state, and control a second valve in the third pipe that branches off from the first pipe that transports the second heat medium to be in an open state.

17. The temperature control device according to claim 16, further comprising:
a first tank arranged at a position lower than that of the target member, connected to the plurality of third pipes, and capable of retaining a heat medium; and
a first exhaust depressurizing an interior of the first tank,
wherein the controller circuitry is configured to control the first exhaust to depressurize the interior of the first tank and control the second valve in the third pipe to be in the open state, the third pipe branching off from the first pipe that transports the second heat medium.

18. The temperature control device according to claim 16, further comprising:
a gas supply connected to the plurality of third pipes and supplying a purge gas to the plurality of third pipes,
wherein the controller circuitry is configured to control, when the first heat medium is caused to flow to the plurality of flow paths, the gas supply to supply the purge gas to the third pipe that branches off from the first pipe that transports the second heat medium other than the first heat medium.

19. The temperature control method according to claim 15, further comprising:
a process of depressurizing an interior of a first tank connected to a plurality of third pipes that respectively branch off from a plurality of first pipes at positions on one side of first valves in the first pipes, the one side being toward the plurality of flow paths, and the first pipes respectively connecting one end of the plurality of flow paths and the heat medium supply to each other,
wherein the process of causing the second heat medium to be discharged comprises causing the second heat medium to be sucked into the first tank by the depressurizing of the interior of the first tank.

20. The temperature control method according to claim 15, further comprising:
a process of supplying a purge gas from a gas supply to a third pipe that branches off from a first pipe that transports the second heat medium other than the first heat medium, the first pipe connecting one end of a flow path in the component and the heat medium supply to each other,
wherein the process of causing the second heat medium to be discharged comprises causing the second heat medium to flow out of the flow path by the supplying of the purge gas.
